(19) United States
(12) Patent Application Publication
(10) Pub. No.: US 2026/0073964 A1
(43) Pub. Date: Mar. 12, 2026

(54) DISTURB MITIGATION SCHEME FOR FERROELECTRIC FIELD-EFFECT TRANSISTORS

(71) Applicant: Samsung Electronics Co., Ltd., Suwon-si (KR)

(72) Inventors: Kijoon KIM, Hwaseong-si (KR); Prasanna Venkatesan RAVINDRAN, Atlanta, GA (US); Asif KHAN, Atlanta, GA (US); Kwangsoo KIM, Suwon-si (KR); Wanki KIM, Suwon-si (KR); Jongho WOO, Suwon-si (KR); Suhwan LIM, Suwon-si (KR); Daewon HA, Suwon-si (KR); Dipjyoti DAS, Atlanta, GA (US); Hang CHEN, Atlanta, GA (US); Lance FERNANDES, Atlanta, GA (US); Mengkun TIAN, Atlanta, GA (US); Nashrah AFROZE, Atlanta, GA (US); Priyankka GUNDLAPUDI RAVIKUMAR, Atlanta, GA (US); Shimeng YU, Atlanta, GA (US); Suman DATTA, Atlanta, GA (US); Winston CHERN, Atlanta, GA (US)

(73) Assignees: Samsung Electronics Co., Ltd., Suwon-si (KR); Georgia Tech Research Corporation, Atlanta, GA (US)

(21) Appl. No.: 19/322,156

(22) Filed: Sep. 8, 2025

Related U.S. Application Data
(60) Provisional application No. 63/692,275, filed on Sep. 9, 2024.

(51) Int. Cl. G11C 11/22; G11C 5/06; G11C 16/04; H10B 51/30; H10D 30/69

(52) U.S. Cl. CPC G11C 11/2275; G11C 5/063; G11C 11/223; G11C 11/2293; G11C 16/0483; H10B 51/30; H10D 30/701

(57) ABSTRACT

A memory device may include processing circuitry connected to a ferroelectric transistor through a word line and a bit line. The ferroelectric transistor may include an interfacial layer between a gate electrode and a semiconductor layer, and a ferroelectric layer between the interfacial layer and the gate electrode. The processing circuitry may be configured to perform an operation to reduce disturb in the ferroelectric transistor by applying a mitigation pulse to the gate electrode of the ferroelectric transistor using the word line and then applying a program pulse to the gate electrode of the ferroelectric transistor using the word line. The mitigation pulse and the program pulse may have opposite polarities. A level of the program pulse may be sufficient to program a desired program state in the ferroelectric transistor. A level of the mitigation pulse may be sufficient to detrap electrons in the ferroelectric transistor.

### CROSS-REFERENCE TO RELATED APPLICATION(S)

This application claims the benefit of U.S. Provisional Application No. 63/692,275, filed on Sep. 9, 2024, the entire disclosure of which is incorporated herein by reference.

### STATEMENT REGARDING DISCLOSURE BY INVENTOR

The subject matter of Venkatesan et al., Disturb and its Mitigation in Ferroelectric Field-Effect Transistors With Large Memory Window for NAND Flash Applications, IEEE Electron Device Letters, Vol. 45, No. 12, pp. 2367-2370 December 2024, was invented by joint inventors named on the present application, and the entire contents of which are incorporated herein by reference. Additionally, Chingsung Park, Taeyoung Song, and Souvik Mahaptra are co-authors of “Disturb and its Mitigation in Ferroelectric Field-Effect Transistors With Large Memory Window for NAND Flash Applications” article, but Chingsung Park, Taeyoung Song, and Souvik Mahaptra are not inventors of the subject matter claimed in the present application as originally filed.

### BACKGROUND

Incorporating ferroelectrics as a replacement for the charge trap nitride (CTN) layer in NAND devices has recently gained attention for next generation vertical NAND (V-NAND) technology. Replacing the CTN layer in NAND devices with ferroelectrics may form ferroelectric field-effect transistors (FEFETs) in the NAND devices.

However, NAND devices with FEFETs may face reliability challenges, such as disturb. Accordingly, there is interest in developing methods for reducing disturb in NAND devices with FEFETs.

### SUMMARY

Example embodiments of the present disclosure relates to a memory device configured to reduce disturb by performing an operation to reduce disturb and/or a method of operating the memory device.

Example embodiments of the present disclosure relate to a memory device configured to reduce disturb by performing a disturb mitigation scheme including an operation to reduce disturb and/or a method of operating the memory device.

According to an example embodiment, a memory device may include a ferroelectric transistor including a semiconductor layer, a gate electrode on the semiconductor layer, an interfacial layer between the gate electrode and the semiconductor layer, and a ferroelectric layer between the interfacial layer and the gate electrode; a word line connected to the gate electrode; a bit line connected a drain region of the semiconductor layer; and processing circuitry connected to the ferroelectric transistor through the word line and the bit line. The processing circuitry may be configured to perform an operation to reduce disturb in the ferroelectric transistor by applying a mitigation pulse to the gate electrode of the ferroelectric transistor using the word line and then applying a program pulse to the gate electrode of the ferroelectric transistor using the word line. A polarity of the mitigation pulse may be opposite a polarity of the program pulse. A level of the program pulse may correspond to a level of a write voltage sufficient to program a desired program state in the ferroelectric transistor.

In some embodiments, the mitigation pulse may be negative and a level of the mitigation pulse may be sufficient to detrap electrons in the ferroelectric transistor. The level of the program pulse may be positive relative to a source region of the semiconductor layer. In the operation to reduce disturb, the applying the program pulse to the gate electrode of the ferroelectric transistor may be performed immediately after the applying the mitigation pulse to the gate electrode of the ferroelectric transistor without a delay time in between.

In some embodiments, the ferroelectric layer may be a first ferroelectric layer. The ferroelectric transistor may further include a tunnel dielectric layer on the first ferroelectric layer and a second ferroelectric layer on the tunnel dielectric layer. The interfacial layer may include an oxide of a material of the semiconductor layer. The gate electrode may be on the second ferroelectric layer. The ferroelectric transistor may be a memory cell in a memory cell array of the memory device.

In some embodiments, the first ferroelectric layer and the second ferroelectric layer each may include hafnium zirconium oxide. The interfacial layer, the first ferroelectric layer, the tunnel dielectric layer, and the second ferroelectric layer may be stacked directly on top of each other between the semiconductor layer and the gate electrode. The material of the semiconductor layer may include silicon. A thickness of a stack including the first ferroelectric layer, the tunnel dielectric layer, and the second ferroelectric layer may be less than or equal to 20 nm in a direction from the interfacial layer to the gate electrode.

In some embodiments, the memory device may further include a substrate. The semiconductor layer may be on a surface of the substrate and may extend in a direction perpendicular to the surface of the substrate. The interfacial layer, the first ferroelectric layer, the tunnel dielectric layer, the second ferroelectric layer, and the gate electrode may sequentially surround the semiconductor layer.

In some embodiments, the processing circuitry may be configured to periodically perform the operation to reduce disturb in the ferroelectric transistor a plurality of times after the processing circuitry performs one program operation on the ferroelectric transistor. The processing circuitry may include a timing circuit configured to control a time interval between each of the plurality of times the processing circuitry performs the operation to reduce disturb.

In some embodiments, a threshold voltage of the ferroelectric transistor may change from a first level to a second level that is higher than the first level after the processing circuitry applies a plurality of pass pulses to the ferroelectric transistor through the word line following the processing circuitry performing one program operation on the ferroelectric transistor. A level of the plurality of pass pulses may be greater than the threshold voltage of the ferroelectric transistor and less than the level of the program pulse. The plurality of pass pulses may be a same polarity as the program pulse. The processing circuitry may be configured to restore the threshold voltage of the ferroelectric transistor from the second level to the first level by performing the operation to reduce disturb.

In some embodiments, the processing circuitry may be configured to perform the operation to reduce disturb in the ferroelectric transistor in response to the processing circuitry reading a current of the ferroelectric transistor and detecting the current of the ferroelectric transistor is greater than or equal to a reference current.

In some embodiments, the processing circuitry may include a counter circuit configured to count a number of pass pulses applied to the ferroelectric transistor after an event. The event may be a most recent operation among a program operation on the ferroelectric transistor or a last time the operation to reduce disturb was performed on the ferroelectric transistor. The processing circuitry may be configured to perform the operation to reduce disturb in the ferroelectric transistor in response to the processing circuitry detecting the number of pass pulses applied to the ferroelectric transistor after the event is greater than or equal to a threshold level.

According to an example embodiment, a memory device may include a substrate; a memory cell array including a plurality of NAND strings on the substrate; and processing circuitry connected to the plurality of NAND strings of the memory cell array through a plurality of word lines and a plurality of bit lines. The plurality of NAND strings each may include a plurality of ferroelectric transistors connected in series between a first select transistor and a second select transistor. The processing circuitry may be configured to reduce disturb in the memory cell array by performing an operation to reduce disturb. In each corresponding ferroelectric transistor among the plurality of ferroelectric transistors in a corresponding NAND string among the plurality of NAND strings, the operation to reduce disturb may include applying a mitigation pulse to a gate electrode of the corresponding ferroelectric transistor followed by a program pulse to the gate electrode of the corresponding ferroelectric transistor. The processing circuitry may be configured to apply the mitigation pulse and the program pulse to the corresponding ferroelectric transistor using a corresponding word line among the plurality of word lines and a corresponding bit line among the plurality of bit lines. The corresponding word line may be connected to the corresponding ferroelectric transistor. The corresponding bit line may be connected to the corresponding NAND string. A polarity of the mitigation pulse may be opposite a polarity of the program pulse. A level of the mitigation pulse may be sufficient to detrap electrons in the corresponding ferroelectric transistor. A level of the program pulse may correspond to a level of a write voltage sufficient to program a desired program state in the corresponding ferroelectric transistor.

In some embodiments, in the operation to reduce disturb, the program pulse may be applied to the gate electrode of the corresponding ferroelectric transistor immediately after the mitigation pulse is applied to the gate electrode of the corresponding ferroelectric transistor without a delay time in between.

In some embodiment embodiments, in the memory cell array, the plurality of NAND strings may include a first NAND string and a second NAND string extending in a direction perpendicular to an upper surface of the substrate. The plurality of word lines may include 1 to N word lines at different levels over the upper surface of the substrate. N may be an integer corresponding to a number of the plurality of ferroelectric transistors in the first NAND string and the second NAND string, respectively. Each of the 1 to N word lines may be connected to one of the plurality of ferroelectric transistors in the first NAND string and one of the plurality of ferroelectric transistors in the second NAND string at a same level. The plurality of bit lines may include a first bit line electrically connected to a first end of the first NAND string and a second bit line electrically connected to a first end of the second NAND string. The first bit line may not be electrically connected to the second NAND string and the second bit line is not electrically connected to the first NAND string. The processing circuitry may be connected to the first select transistor of the first NAND string and the first select transistor of the second NAND string through a first select line. The processing circuitry may be connected to the second select transistor of the first NAND string and the second select transistor of the second NAND string through a second select line.

In some embodiments, in the memory cell array, the plurality of NAND strings each may include a semiconductor layer extending in a direction perpendicular to a surface of the substrate, an interfacial layer surrounding the semiconductor layer and containing an oxide of a material of the semiconductor layer, a ferroelectric (FE) stack surrounding the interfacial layer, and a plurality of gate electrodes surrounding the FE stack and spaced apart from each other on the FE stack in a direction perpendicular to the surface of the substrate. The FE stack may include one ferroelectric layer or the FE stack may include a plurality of ferroelectric layers extending in the direction perpendicular to the surface of the substrate and separated from each other by a tunnel dielectric layer.

In some embodiments, in the plurality of NAND strings, the plurality of gate electrodes may be alternately stacked with a plurality of insulating layers in the direction perpendicular to the surface of the substrate. The plurality of insulating layers may surround the FE stack. The FE stack may include the plurality of ferroelectric layers extending the direction perpendicular to the surface of the substrate and separated from each other by the tunnel dielectric layer. The interfacial layer may directly contact the semiconductor layer. The gate electrode may directly contact the FE stack.

In some embodiments, the processing circuitry may be configured to periodically perform the operation to reduce disturb on one or more of the plurality of ferroelectric transistors in one or more of the plurality of NAND strings after the one or more of the plurality of ferroelectric transistors in the one or more of the plurality of NAND strings are programmed. The processing circuitry may include a timing circuit configured to control a time interval between a plurality of times the processing circuitry periodically performs the operation to reduce disturb on the one or more of the plurality of ferroelectric transistors in the one or more of the plurality of NAND strings after the after the one or more of the plurality of ferroelectric transistors in the one or more of the plurality of NAND strings are programmed.

In some embodiments, the processing circuitry may be configured to restore one or more threshold voltages of one or more of the plurality of ferroelectric transistors in one or more of the plurality of NAND strings from one or more drifted threshold voltages to one or more desired threshold voltages, respectively, by performing the operation to reduce disturb on the one or more of the plurality of ferroelectric transistors in the one or more of the plurality of NAND strings. The processing circuitry may be configured to restore a threshold voltage of a disturbed ferroelectric transistor among one or more of the plurality of ferroelectric transistors in one or more of the plurality of NAND strings from a drifted threshold voltage to a desired threshold voltage by performing the operation to reduce disturb on the disturbed ferroelectric transistor.

In some embodiments, the processing circuitry may include a counter circuit configured to count a number of pass pulses applied to the corresponding ferroelectric transistor after the processing circuitry performs one program operation on the corresponding ferroelectric transistor or after the processing circuitry performs the operation to reduce disturb on the corresponding ferroelectric transistor. The processing circuitry may be configured to perform the operation to reduce to disturb on the corresponding ferroelectric transistor in response the processing circuitry detecting the number of pass pulses applied to the corresponding ferroelectric transistor is greater than or equal to a threshold value.

In some embodiments, the processing circuitry may be configured to detect a disturbed ferroelectric transistor among the plurality of ferroelectric transistors in the plurality of NAND strings in response to the processing circuitry reading a current of one of the plurality of ferroelectric transistors in one of the plurality of NAND strings and the processing circuitry detecting the current is greater than or equal to a reference current. In some embodiments, the processing circuitry may be configured to perform the operation to reduce disturb on the disturbed ferroelectric transistor in response to the processing circuitry detecting the disturbed ferroelectric transistor.

According to an example embodiment, a memory device may include a substrate; a memory cell array including a plurality of NAND strings on the substrate, the plurality of NAND strings each including a plurality of ferroelectric transistors connected in series between a first select transistor and a second select transistor; and processing circuitry connected to the plurality of NAND strings of the memory cell array through a plurality of word lines and a plurality of bit lines. The processing circuitry may be configured to reduce disturb in the memory cell array by performing a disturb mitigation scheme. In each corresponding ferroelectric transistor among the plurality of ferroelectric transistors in a corresponding NAND string among the plurality of NAND strings, the disturb mitigation scheme may include periodically performing an operation to reduce disturb on the corresponding ferroelectric transistor. The disturb mitigation scheme may be performed in response to the processing circuitry detecting the operation to reduce disturb is needed for the corresponding ferroelectric transistor. The operation to reduce disturb may include applying a mitigation pulse to a gate electrode of the corresponding ferroelectric transistor followed by a program pulse to the gate electrode of the corresponding ferroelectric transistor. The processing circuitry may apply the mitigation pulse and the program pulse to the corresponding ferroelectric transistor using a corresponding word line among the plurality of word lines and a corresponding bit line among the plurality of bit lines. The corresponding word line may be connected to the corresponding ferroelectric transistor. The corresponding bit line may be connected to the corresponding NAND string. A polarity of the mitigation pulse may be opposite a polarity of the program pulse. A level of the mitigation pulse may be sufficient to detrap electrons in the corresponding ferroelectric transistor. A level of the program pulse may correspond to a level of a write voltage sufficient to program a desired program state in the corresponding ferroelectric transistor.

According to an example embodiment, a method of operating a memory device may include performing a program operation on a ferroelectric transistor of the memory device; and performing an operation to reduce disturb in the ferroelectric transistor after the performing the program operation on the ferroelectric transistor. The ferroelectric transistor may include a semiconductor layer, a gate electrode on the semiconductor layer, an interfacial layer between the gate electrode and the semiconductor layer, and a ferroelectric layer between the interfacial layer and the gate electrode. The operation to reduce disturb may include applying a mitigation pulse to the gate electrode of the ferroelectric transistor using a word line and then applying a program pulse to the gate electrode of the ferroelectric transistor using the word line. A polarity of the mitigation pulse is opposite a polarity of the program pulse. A level of the program pulse may correspond to a level of a write voltage sufficient to program a desired program state in the ferroelectric transistor. The mitigation pulse may be negative. A level of the mitigation pulse may be sufficient to detrap electrons in the ferroelectric transistor.

In some embodiments, the ferroelectric layer may be one single ferroelectric layer directly between the interfacial layer and the gate electrode. Alternatively, the ferroelectric layer may include a first ferroelectric layer, a tunnel dielectric layer on the first ferroelectric layer, and a second ferroelectric layer on the tunnel dielectric layer.

In some embodiments, the method may include periodically repeating the operation to reduce disturb in the ferroelectric transistor a plurality of times according to a time interval after the performing the program operation on the ferroelectric transistor of the memory device is performed a single time.

In some embodiments, the performing the operation to reduce disturb in the ferroelectric transistor may be performed in response to detecting a current of the ferroelectric transistor is greater than a reference current.

In some embodiments, the performing the operation to reduce disturb in the ferroelectric transistor may be performed in response to detecting a number of pass voltages applied to the ferroelectric transistor following an event is greater than or equal to a threshold value. The event may be a most recent operation on the ferroelectric transistor among the program operation or a last time the performing the operation to reduce disturb in the ferroelectric transistor was performed.

According to an example embodiment, a method of operating a memory device may include reducing disturb in a memory cell array including a plurality of NAND strings on a substrate, the plurality of NAND strings each including a plurality of ferroelectric transistors connected in series between a first select transistor and a second select transistor, and the memory device including processing circuitry connected to the plurality of NAND strings of the memory cell array through a plurality of word lines and a plurality of bit lines. The reducing disturb may include performing an operation to reduce disturb using the processing circuitry, In each corresponding ferroelectric transistor among the plurality of ferroelectric transistors in a corresponding NAND string among the plurality of NAND strings, the operation to reduce disturb may include applying a mitigation pulse to a gate electrode of the corresponding ferroelectric transistor followed by a program pulse to the gate electrode of the corresponding ferroelectric transistor. The mitigation pulse and the program pulse may be applied to the corresponding ferroelectric transistor using a corresponding word line among the plurality of word lines and a corresponding bit line among the plurality of bit lines. The corresponding word line may be connected to the corresponding ferroelectric transistor. The corresponding bit line may be connected to the corresponding NAND string. A polarity of the mitigation pulse may be opposite a polarity of the program pulse. A level of the mitigation pulse may be sufficient to detrap electrons in the corresponding ferroelectric transistor. A level of the program pulse may correspond to a level of a write voltage sufficient to program a desired program state in the corresponding ferroelectric transistor.

In some embodiments, in the memory cell array, the plurality of NAND strings each may include a semiconductor layer extending in a direction perpendicular to a surface of the substrate, an interfacial layer surrounding the semiconductor layer and containing an oxide of a material of the semiconductor layer, a FE stack surrounding the interfacial layer, and a plurality of gate electrodes surrounding the FE stack and spaced apart from each other on the FE stack in a direction perpendicular to the surface of the substrate. The FE stack may include one ferroelectric layer, or the FE stack may include a plurality of ferroelectric layers extending in the direction perpendicular to the surface of the substrate and separated from each other by a tunnel dielectric layer.

In some embodiments, the method may further include periodically performing the operation to reduce disturb on one or more of the plurality of ferroelectric transistors in one or more of the plurality of NAND strings after the after the one or more of the plurality of ferroelectric transistors in the one or more of the plurality of NAND strings are programmed. The periodically performing the operation to reduce disturb may be performed according to a time interval between each operation to reduce disturb.

In some embodiments, the operation to reduce disturb may be performed on the corresponding ferroelectric transistor in response to detecting a current of the corresponding ferroelectric transistor is greater than or equal to a reference current.

In some embodiments, the operation to reduce disturb may be performed on the corresponding ferroelectric transistor in response detecting a number of pass pulses applied to the corresponding ferroelectric transistor following an event is greater than or equal to a threshold value. The event may be a most recent operation on the corresponding ferroelectric transistor among a program operation or a last time the performing the operation to reduce disturb was performed on the corresponding ferroelectric transistor.

According to an example embodiment, a method of operating a memory device may include reducing disturb in a memory cell array including a plurality of NAND strings on a substrate, the plurality of NAND strings each including a plurality of ferroelectric transistors connected in series between a first select transistor and a second select transistor, and the memory device including processing circuitry connected to the plurality of NAND strings of the memory cell array through a plurality of word lines and a plurality of bit lines. The reducing disturb may include performing a disturb mitigation scheme in the memory cell array using the processing circuitry. In each corresponding ferroelectric transistor among the plurality of ferroelectric transistors in a corresponding NAND string among the plurality of NAND strings, the disturb mitigation scheme may include periodically performing an operation to reduce disturb on the corresponding ferroelectric transistor. The operation to reduce disturb may include applying a mitigation pulse to a gate electrode of the corresponding ferroelectric transistor followed by a program pulse to the gate electrode of the corresponding ferroelectric transistor. The mitigation pulse and the program pulse may be applied to the corresponding ferroelectric transistor using a corresponding word line among the plurality of word lines and a corresponding bit line among the plurality of bit lines. The corresponding word line may be connected to the corresponding ferroelectric transistor. The corresponding bit line may be connected to the corresponding NAND string. A polarity of the mitigation pulse may be opposite a polarity of the program pulse. A level of the mitigation pulse may be sufficient to detrap electrons in the corresponding ferroelectric transistor, and a level of the program pulse may correspond to a level of a write voltage sufficient to program a desired program state in the corresponding ferroelectric transistor.

In some embodiments, the operation to reduce disturb may be periodically performed in response to the processing circuitry detecting the operation to reduce disturb is needed for the corresponding ferroelectric transistor.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a cross-sectional diagram of a ferroelectric gate stack having a single ferroelectric (FE) layer according to an example embodiment of the present disclosure;

FIG. 1B is a cross-sectional diagram of an engineered ferroelectric gate stack according to an example embodiment of the present disclosure;

FIGS. 2A and 2B are cross-sectional diagrams of ferroelectric field effect transistors (FEFETs) according to example embodiments of the present disclosure;

FIG. 3A is a block diagram of a memory device according to a comparative example;

FIG. 3B is an example diagram for a portion of a memory block in the memory cell array in the memory device of FIG. 3A;

FIG. 4A illustrates a TEM image and an I_{D}-V_{G} curve showing the memory window (MW) and pass voltages of an example FEFET having a single ferroelectric (FE) layer;

FIG. 4B illustrates a TEM image and an I_{D}-V_{G} curve showing the memory window (MW) and pass voltages of an example FEFET having an engineered ferroelectric gate stack;

FIG. 4C is a graph showing the memory windows (MWs) versus Vwrite for the example FEFETs having the single ferroelectric (FE) layer and the engineered ferroelectric gate stack;

FIG. 4D is a graph showing the threshold voltage (Vt) retention at room temperature (RT) and 50° C. for an example FEFET having an engineered ferroelectric gate stack;

FIG. 5A is a diagram illustrating a pulse scheme for disturb characterization of FEFETs according to experimental examples;

FIG. 5B is a diagram illustrating characterization of FEFET threshold voltages according to experimental examples;

FIG. 5C is a schematic of a gate stack and band diagram for explaining electron injection from the channel side when the positive pass voltage is applied to the gate electrode of a FEFET having an engineering ferroelectric gate stack;

FIG. 6A is a diagram illustrating a disturb mitigation pulse scheme including an operation to reduce disturb according to an example embodiment;

FIG. 6B includes I_{D}-V_{G} curves for standard and band-engineered FEFETs after different numbers of disturb cycles.

FIG. 6C illustrates the evolution of threshold voltage (V_{T}) and ΔV_{T} for standard and band-engineered FEFETs in threshold voltage according to experimental examples.

FIGS. 7A and 7B are graphs illustrating the efficacy of a disturb mitigation scheme on band-engineered FEFETs according to experimental examples.

FIG. 8A is a block diagram of a memory device according to an example embodiment;

FIG. 8B is an example diagram for a portion of a memory block in the memory cell array in the memory device of FIG. 8A;

FIG. 8C is a diagram illustrating an enlarged view of a FEFET in the portion of the memory block in FIG. 8B.

FIG. 9 is a flow chart for a method of operating a memory device according to an example embodiment.

FIG. 10A is a flowchart for describing an operation for detecting whether an operation to reduce disturb is needed according to an example embodiment;

FIG. 10B is a flowchart for describing an operation for detecting whether an operation to reduce disturb is needed according to an example embodiment;

FIG. 10C is a flowchart for describing an operation for detecting whether an operation to reduce disturb is needed according to an example embodiment.

FIG. 11 is a block diagram of a memory system according to an example embodiment.

### DETAILED DESCRIPTION

Hereinafter, embodiments of the present disclosure will be described as follows with reference to the accompanying drawings. Hereinafter, terms such as “upper portion,” “middle portion,” and “lower portion” may be replaced with other terms, for example, “first,” “second,” and “third” to describe elements of the specification. Terms such as “first,” “second,” and “third” may be used to describe different elements, but the elements are not limited by the terms, and a “first element” may be referred to as a “second element.”

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC. As used herein, the singular forms “a,” “an” and “the” are intended to include the plural forms as well, unless the context clearly indicates otherwise.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

The notion that elements are “substantially the same” may indicate that the element may be completely the same and may also indicate that the elements may be determined to be the same in consideration of errors or deviations occurring during a process.

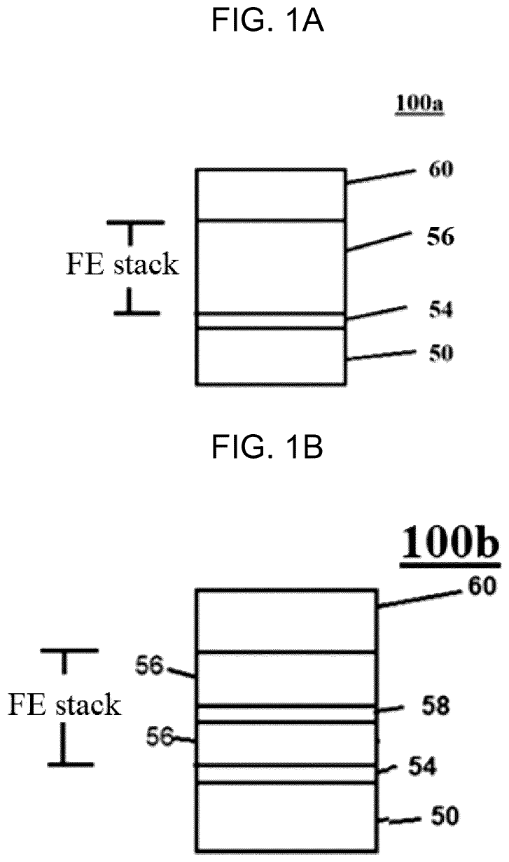

FIG. 1A is a cross-sectional diagram of a ferroelectric gate stack having a single ferroelectric (FE) layer according to an example embodiment of the present disclosure.

Referring to FIG. 1A, a ferroelectric gate stack 100a may include a semiconductor layer 50, a conductor layer 60 facing the semiconductor layer 50, a ferroelectric (FE) stack between the semiconductor layer 50 and the conductor layer 60, and an interfacial layer 54 between the semiconductor layer 50 and the FE stack. The conductor layer 60, FE stack, and semiconductor layer 50 may extend parallel to each other.

The semiconductor layer 50 may include a group IV semiconductor material, a group III-V semiconductor material, an oxide semiconductor material, or a transition metal dichalcogenide (TMD). For example, the semiconductor layer 50 may include silicon (Si) (e.g., monocrystalline Si or polycrystalline Si), germanium (Ge), silicon germanium (SiGe), gallium arsenide (GaAs), gallium nitride (GaN), indium gallium zinc oxide (InGaZnO), graphene, or molybdenum sulfide (MoS₂), but is not limited thereto. The semiconductor layer 50 may be undoped or the semiconductor layer 50 may be doped with a p-type or n-type impurity. The semiconductor layer 50 may correspond to a region of a bulk substrate, a separate layer on the substrate, or a region of the separate layer on the substrate.

The interfacial layer 54 may include an oxide of a material in the semiconductor layer 50. For example, the interfacial layer 54 may include silicon oxide when the semiconductor layer includes silicon.

The FE stack in the ferroelectric gate stack 100a may be a single ferroelectric layer 56 containing a ferroelectric material, such as hafnium zirconium oxide (HZO), a Hf-based oxide, or a Zr-based oxide. The ferroelectric material may have a fluorite crystal structure, but these are just example materials and other fluorite-structured ferroelectric materials may be suitable for the ferroelectric layer 56.

The conductor layer 60 may include an electrically-conductive material such as a metal, a metal alloy, a metal nitride, or a combination thereof. The conductor layer may include tungsten (W), aluminum (Al), molybdenum (Mo), titanium (Ti), tantalum (Ta), TiAl, TiAlN, WN, AlN, TiN, or TaN. or a combination thereof, but is not limited thereto. In some embodiments, the conductor layer 60 may include a multilayer structure having a metal nitride layer and a metal layer or metal alloy layer on the metal nitride layer, where the metal nitride layer may be disposed between the FE stack and the metal or metal alloy layer. For example, the conductor layer 60 may include TiN/W multilayer structure on the FE stack.

FIG. 1B is a cross-sectional diagram of an engineered ferroelectric gate stack according to an example embodiment of the present disclosure.

Referring to FIG. 1B, a ferroelectric gate stack 100b may be the same as the ferroelectric gate stack 100a except for a structure of the FE stack.

In the ferroelectric gate stack 110b, the FE stack may include a plurality of ferroelectric layers 56 separated from each other by a tunnel dielectric layer 58 in contact with the plurality of ferroelectric layers 56. Each tunnel dielectric layer 58 may be sandwiched between a pair of ferroelectric layers 56. The ferroelectric layers 56 each may include a ferroelectric material, such as HZO, a Hf-based oxide, or a Zr-based oxide, and the ferroelectric material may have a fluorite crystal structure, but these are just example materials and other fluorite-structured ferroelectric materials may be suitable for the ferroelectric material regions. The tunnel dielectric layer 58 may include a dielectric material configured to increase a memory window of the FE stack. The dielectric material of the tunnel dielectric layer 58 may be different than the ferroelectric material of the ferroelectric layer 56. For example, the tunnel dielectric layer 58 may be aluminum oxide (Al₂O₃), but other dielectric materials may be used, such as silicon oxide (SiO₂).

Because the FE stack in the ferroelectric gate stack 100b includes the tunnel dielectric layer 58 configured to increase a memory window of the FE stack, the FE stack in the ferroelectric gate stack 100b may be referred to as an engineered FE stack and the ferroelectric gate stack 100b may be referred to as an engineered ferroelectric gate stack in the present disclosure.

Although FIG. 1B illustrates an example with one tunnel dielectric layer 58 between two ferroelectric layers 56, example embodiments are not limited thereto. For example, in other embodiments, the FE stack may include two tunnel dielectric layers 58 separating three ferroelectric layers 56 from each other and so on. For example, although not illustrated in FIG. 1B, in some embodiments, a FE stack may include a first ferroelectric layer, a first tunnel dielectric layer, a second ferroelectric layer, a second tunnel dielectric layer, and a third ferroelectric layer sequentially stacked on top of each other with the conductor layer 60 directly on top of the third ferroelectric layer.

In FIGS. 1A and 1B, a distance between the semiconductor layer 50 and the conductor layer 60 may be 20 nm or less. In other words, a thickness of a stack including the FE stack and interfacial layer 54 may be 20 nm or less. Also, in FIGS. 1A and 1B, adjacent layers may directly contact each other. For example, in FIG. 1A, opposite surfaces of the interfacial layer 54 may directly contact the semiconductor layer 50 and the ferroelectric layer 56, and opposite surfaces of the ferroelectric layer 56 may directly contact the interfacial layer 54 and the conduct layer 60.

In FIG. 1B, the interfacial layer 54 may be directly on the semiconductor layer 50, the first ferroelectric layer 56 (lower ferroelectric layer) may be directly on the interfacial layer 54, the tunnel dielectric layer 58 may be directly on the first ferroelectric layer 56, and the second ferroelectric layer 56 (upper ferroelectric layer) 56 may be directly on the tunnel dielectric layer 58, and the conductor layer 60 may be directly on the second ferroelectric layer 56. The conductor layer 60 may be a gate electrode.

In some embodiments, the conductor layer 60 may not surround the semiconductor layer 50. In other embodiments, the conductor layer 60 may surround the semiconductor layer 50.

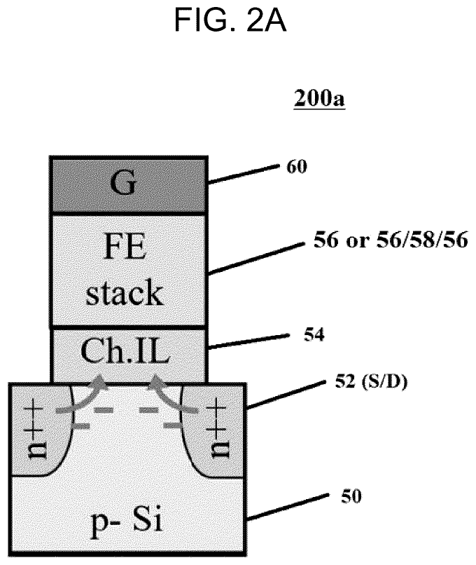

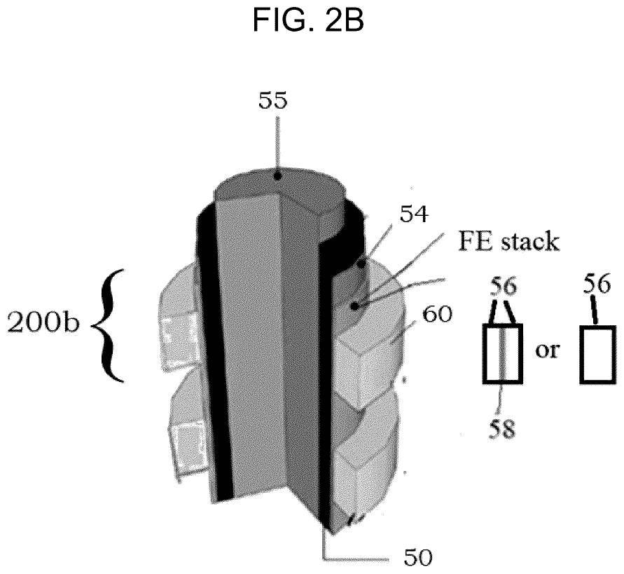

FIGS. 2A and 2B are cross-sectional diagrams of ferroelectric field effect transistors (FEFETs) according to example embodiments of the present disclosure;

Referring to FIG. 2A, in an example embodiment, a ferroelectric field effect transistor (FEFET) 200a may have a structure where the semiconductor layer 50 may be at least part of substrate or the semiconductor layer 50 may be an epitaxial layer on a substrate. The semiconductor layer 50 may include impurity regions 52 spaced apart from each other. The impurity regions 52 may correspond to source/drain (S/D) impurity regions. The interface layer 54 may be on a region of the semiconductor layer 50 between the impurity regions 52, such as directly on the region of the semiconductor layer 50 between the impurity regions 52. The FE stack may be on the interface layer 54. Opposite surface of the interface layer 540 may be between and directly contacting the FE stack and the semiconductor layer 50. The conductor layer 60 may be on the FE stack so opposite surfaces of the FE stack may be between and directly contacting the interface layer 54 and the conductor layer 60.

In FIG. 2A, the FE stack of the FEFET 200a may be include the single ferroelectric layer 56 according to the FE stack of the ferroelectric gate stack 100a in FIG. 1A or the FE stack of the FEFET 200a may include the multilayer FE stack (engineered FE stack including a tunnel dielectric layer 58 between ferroelectric layers 56) according to the FE stack of the ferroelectric gate stack 100b in FIG. 1B.

Referring to FIG. 2B, a FEFET 220b may be defined by a portion of a memory cell stack corresponding to a NAND string.

The memory cell stack may include a plurality of conductor layers 60 and insulating interlayers (not shown) alternately stacked on top of each other. An internal surface of the semiconductor layer 50 may surround an insulating filler layer 55. The insulating filler layer 55 may extend in the same direction as the semiconductor layer 50, which may be a vertical direction. The insulating filler layer 55 may include an insulating material such as silicon oxide. In some embodiments, the insulating filler layer 55 may be omitted and the semiconductor layer 50 may fill the area occupied by the insulating filler layer 55 in FIG. 2B. The interfacial layer 54 may surround an outer surface of the semiconductor layer 50 and may extend in the same direction as the semiconductor layer 50. A FE stack surround an outer surface of the interfacial layer 54 and may extend in the same direction as the semiconductor layer 50, such as the vertical direction. The FE stack may be a single ferroelectric layer 56 or the FE stack include a tunnel dielectric layer 58 separating a plurality of ferroelectric layers 56 such as a tunnel dielectric layer 58 sandwiched between two ferroelectric layers 56. The tunnel dielectric layer 58 may extend in the same direction as the semiconductor layer 50. Each of the plurality of conductor layers 60 in the memory cell stack may surround the FE stack.

An inner surface of the FE stack may directly contact the interfacial layer 54 and an outer surface of the FE stack may directly contact inner surfaces of the plurality of conductor layers 60. For example, when the FE stack is a single ferroelectric layer 56, an inner surface of the single ferroelectric layer 56 may directly contact the interfacial layer 54 and an outer surface of the single ferroelectric layer may contact the inner surfaces of the plurality of conductor layers 60.

When the FE stack includes a tunnel dielectric layer 58 sandwiched between two ferroelectric layers 56, the ferroelectric layer 56 closest to the semiconductor layer 50 may be referred to as the first ferroelectric layer 56 and the ferroelectric layer 56 closest to the conductor layer 60 may be referred to as the second ferroelectric layer 56. Opposite surfaces of the tunnel dielectric layer 58 may directly contact the first ferroelectric layer 56 and the second ferroelectric layer 56, respectively. Opposite surfaces of the interfacial layer 54 may directly contact the first ferroelectric layer 56 and the semiconductor layer 50, respectively.

In FIG. 2B, the FEFET 200b may be defined by one conductor layer 60 surrounding a portion of the semiconductor layer 50 with a portion of the interfacial layer 54 and a portion of the FE stack therebetween. Although not shown in FIG. 2B, opposite ends of the semiconductor layer 50 may be connected to semiconductor impurity regions, such as an impurity region in a semiconductor substrate under the semiconductor layer 50 and an impurity region on top of the semiconductor layer 50, which may provide source/drain impurity regions similar to the impurity regions 52 shown in FIG. 2A. The FE stack may include a single ferroelectric layer 56 or the FE stack may include a tunnel dielectric layer 58 between a pair of ferroelectric layers 56.

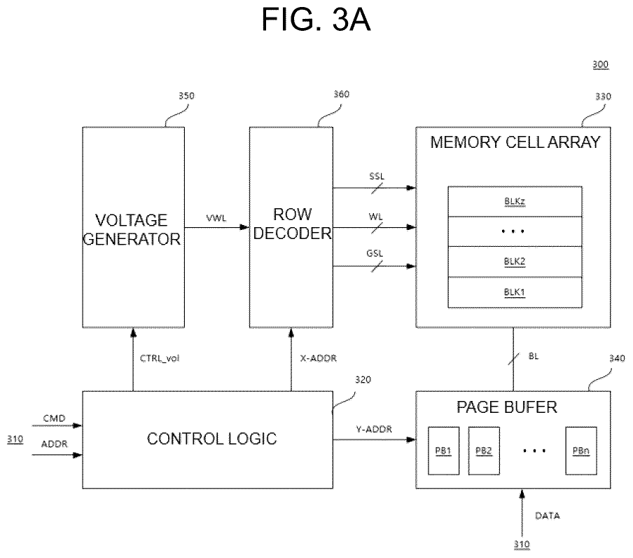

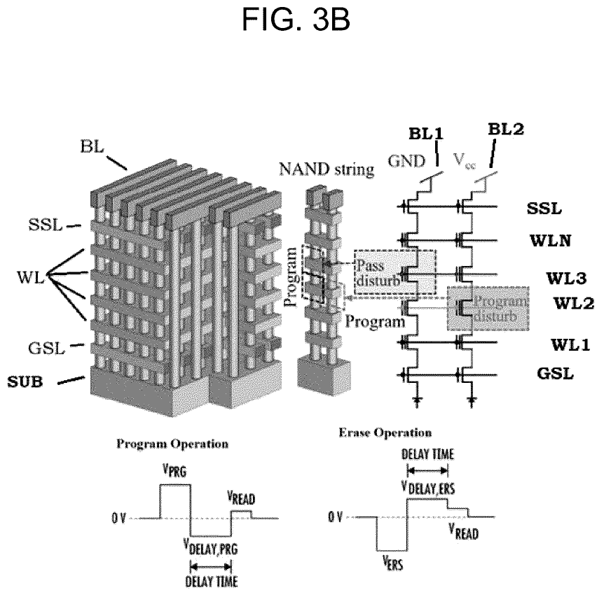

FIG. 3A is a block diagram of a memory device according to a comparative example.

Referring to FIG. 3A, the memory device 300 may include a control logic 320, a memory cell array 330, a page buffer 340, a voltage generator 350, and a row decoder 360.

The control logic 320 may control all various operations of the memory device 300. The control logic 320 may output various control signals in response to commands CMD and/or addresses ADDR from memory interface circuitry 310. For example, the control logic 320 may output a voltage control signal CTRL_vol, a row address X-ADDR, and a column address Y-ADDR. The memory interface circuitry 310 may communicate with a memory controller (not shown), such as a host.

The memory cell array 330 may include a plurality of memory blocks BLK1 to BLKz (here, z is a positive integer), each of which may include a plurality of memory cells. The memory cell array 330 may be connected to the page buffer 340 through bit lines BL and be connected to the row decoder 360 through word lines WL, string selection lines SSL, and ground selection lines GSL.

In the memory cell array 330, each of the plurality of memory blocks BLK1 to BLKz may include a plurality of NAND strings arranged in a row direction and a column direction. Each NAND string may include a plurality of the memory cells arranged in series between a pair of selection transistors (e.g., a string selection transistor and a ground selection transistor), and the memory cells may have structures corresponding to the FEFET 200a in FIG. 2A or the FEFET 200b in FIG. 2B.

The page buffer 340 may include a plurality of page buffers PB1 to PBn (here, n is an integer greater than or equal to 3), which may be respectively connected to the memory cells through a plurality of bit lines BL. The page buffer 340 may select at least one of the bit lines BL in response to the column address Y-ADDR. The page buffer 340 may operate as a write driver or a sense amplifier according to an operation mode. For example, during a program operation, the page buffer 340 may apply a bit line voltage corresponding to data to be programmed, to the selected bit line. During a read operation, the page buffer 340 may sense current or a voltage of the selected bit line BL and sense data stored in the memory cell.

The voltage generator 350 may generate various kinds of voltages for program, read, and erase operations based on the voltage control signal CTRL_vol. For example, the voltage generator 350 may generate a program voltage, a read voltage, a program verification voltage, and an erase voltage as a word line voltage VWL.

The row decoder 360 may select one of a plurality of word lines WL and select one of a plurality of string selection lines SSL in response to the row address X-ADDR. For example, the row decoder 360 may apply the program voltage and the program verification voltage to the selected word line WL during a program operation and apply the read voltage to the selected word line WL during a read operation.

The control logic 320 may connect to memory cells including FEFETs in the memory cell array 330. The control logic 320 may be configured to switch a polarization state in the ferroelectric layers of the memory cells by controlling a program voltage or an erase voltage applied to the memory cell.

FIG. 3B is an example diagram for a portion of a memory block in the memory cell array in the memory device of FIG. 3A.

Referring to FIG. 3B, the plurality of NAND strings may be part of a same memory block and may extend in a direction perpendicular to a substrate.

Referring to FIGS. 3A and 3B, the control logic 320 may be configured to control a memory operation on a FEFET in a selected memory cell in the memory cell array 330 by sequentially applying a pulse voltage using the conductor layer to the memory cell, applying a bias voltage to memory cell using the conductor layer, and applying a read voltage to the memory cell using the conductor layer. The pulse voltage may be a program pulse voltage V_{PRG} or an erase pulse voltage V_{ERS}, but is not limited thereto. A sign of the program pulse voltage V_{PRG} may be opposite a sign of the erase pulse voltage V_{ERS}. The bias voltage (V_{DELAY.PRG} Or V_{DELAY.ERS}) may be an opposite polarity and a lower magnitude than the polarity of the pulse voltage. A magnitude of the read voltage VREAD may be less than a magnitude of the program pulse voltage V_{PRG} and a less than a magnitude of the erase pulse voltage V_{ERS}. Applying the bias voltage (V_{DELAY.PRG} or V_{DELAY.ERS}) after the pulse voltage (e.g., V_{PRG} Or V_{ERS}) causes a delay time.

During read and write operations, a pass voltage greater than the threshold voltage (V_{T}) of the erase (ERS) state may be applied to turn on unaddressed cells in the bit line BL. NAND devices with FEFETS may be susceptible to disturb because FEFETs, which operate through the interplay between trap dynamics and polarization switching, may be susceptible to these pass voltages. The pass voltage may cause a change in a state of one or more unselected cells, leading to disturb such as an undesired change in a threshold voltage of a cell.

For example, referring to the circuit diagram of the two NAND strings in FIG. 3B, a ground voltage GND may be applied to the bit line connected to the left NAND string, which may be a selected NAND string, and a positive power supply voltage Vcc may be applied to the right NAND string, which may be an unselected NAND string. When the FEFET labeled “Program” in the left NAND string is programmed, unselected FEFETs in the left NAND string may be affected by “Pass disturb,” particularly FEFETs adjacent to the FEFET labeled “Program.” The FEFET labeled “Program disturb” in the right NAND string may be affected by program disturb. The FEFETs labeled “Program” and “Program disturb” may be connected the same word line and different bit lines. For example, in FIG. 3B, the FEFET labeled “Program” is connected to bit line BL1 and wordline WL2, the FEFET labeled “Pass disturb” is connected to bit line BL1 and wordline WL3, and the FEFET labeled “Program disturb” is connected to bit line BL2 and wordline WL2. While four word lines WL1 to WLN are shown between the ground selection line GSL and string selection line SSL in FIG. 3B, this is just an example and the number of word line lines may vary depending on the number of FEFETs in each NAND string. In FIG. 3B, the bit line BL1 may be connected to the NAND string including the FEFET labeled “Program” and not connected to the NAND string including the FEFET labeled “Program Disturb.” The bit line BL2 may not be connected to the NAND string including the FEFET labeled “Program” and may be connected to the NAND string including the FEFET labeled “Program Disturb.” Each of the word lines WL1 to WLN may be connected to one of the ferroelectric transistors in the left NAND string and one of the ferroelectric transistors in the right NAND string at a same level over the substrate SUB. The control logic 320 may be connected to selection transistors in the left NAND string and right NAND string through the ground selection line GSL and string selection line SSL, respectively.

### Examples for Disturb Characterization

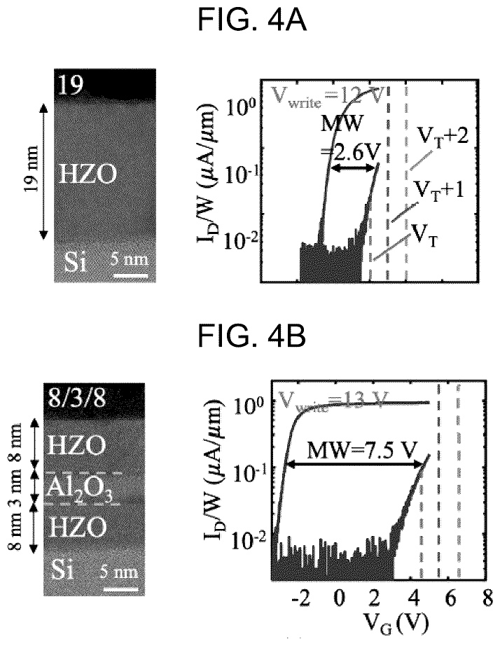

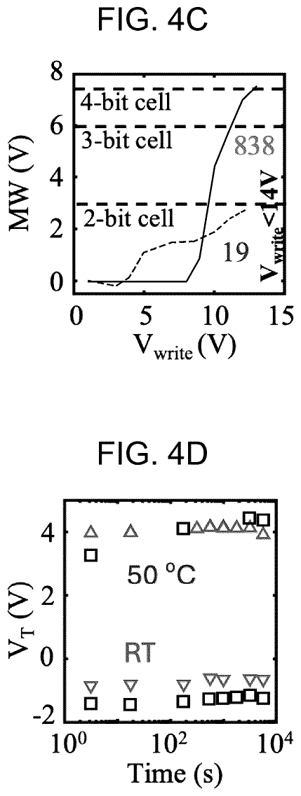

Referring to FIGS. 4A to 4D, examples of a FEFET with the single ferroelectric layer FE stack and the band-engineered FE stack are described for explaining disturb characterization experiments. However, these examples are non-limiting, and inventive concepts are not limited to the examples and disturb characterization described with reference to FIGS. 4A to 4C.

FIG. 4A illustrates a TEM image and an I_{D}-V_{G} curve showing the memory window (MW) and pass voltages of an example FEFET having a single ferroelectric (FE) layer. FIG. 4B illustrates a TEM image and an I_{D}-V_{G} curve showing the memory window (MW) and pass voltages of an example FEFET having an engineered ferroelectric gate stack. FIG. 4C is a graph showing the memory windows (MW) versus Vwrite for the example FEFETs having the single ferroelectric (FE) layer and the engineered ferroelectric gate stack.

### Standard FEFET

Referring to FIG. 4A, FIG. 4A shows a TEM image for an example FEFET having a single ferroelectric layer for the FE stack. The example FEFET shown in FIG. 4A was fabricated with a Si semiconductor layer, a 1 nm SiO₂ interfacial layer on the Si semiconductor layer, a 19 nm hafnium zirconium oxide (HZO) layer of Hf_{0.5}Zr_{0.5}O₂ on the 1 nm SiO₂ interfacial layer, and a conductor layer on the 19 nm HZO layer. The example FEFET shown in FIG. 4A may be referred as the Standard FEFET.

### Band-Engineered FEFET

Referring to FIG. 4B, FIG. 4B shows a TEM image for an example FEFET having an engineered FE stack. The example FEFET shown in FIG. 4B was fabricated with a Si semiconductor layer, a 1 nm SiO₂ interfacial layer on the Si semiconductor layer, a first ferroelectric layer including 8 nm of HZO on the 1 nm SiO₂ interfacial layer, a 3 nm tunnel dielectric layer including Al₂O₃ on the first ferroelectric layer, a second ferroelectric layer including 8 nm of HZO on the tunnel dielectric layer, and a conductor layer on the second ferroelectric layer including 8 nm of HZO. The example FEFET shown in FIG. 4B may be referred as the Band-engineered FEFET.

The I_{D}-V_{G} curves in FIGS. 4A and 4B shows the example Standard FEFET in FIG. 4A has a memory window (MW) of approximately 2.6V and the example Band-engineered FEFET in FIG. 4B has a MW of approximately 7.5V. The threshold voltages V_{T} were extracted from the I_{D}-V_{G} curves in FIGS. 4A and 4B.

FIG. 4C is a graph showing the memory windows (MW) versus Vwrite characteristics were evaluated for the example FEFETs having the single ferroelectric (FE) layer and the engineered ferroelectric gate stack. In FIG. 4C, the Standard FEFET from FIG. 4A is labeled as “19” and the Band-engineered FEFET from FIG. 4B (Example 2) is labeled as “838.” The MWs were evaluated for 10 μs-long symmetric PGM and ERS pulses.

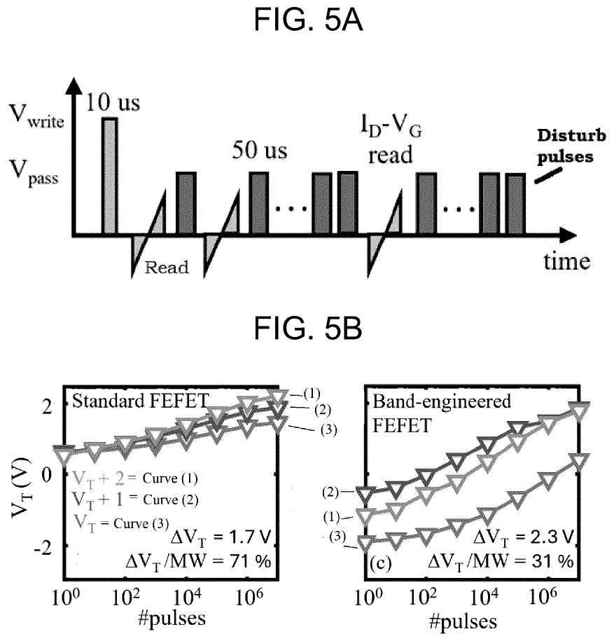

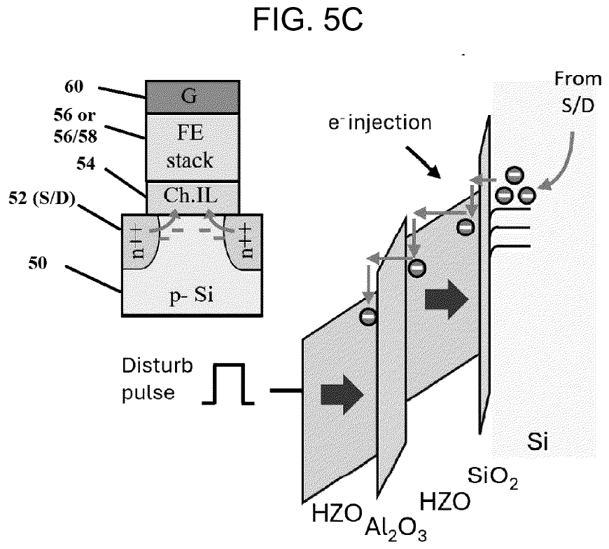

Without wishing to be bound by theory, the inventors of the present application attribute the enhanced MW for the example FEFET having the engineered FE stack (Band-engineered FEFET corresponding to curve “838” in FIG. 4C) compared to the example FEFET having the single ferroelectric layer for the FE stack (Standard FEFET corresponding curve “19” in FIG. 4C) to trapped charges at the ferroelectric layer-tunnel dielectric layer interface (FE-DE interface). Unlike the trapped charges at the ferroelectric-interfacial layer (Ch. IL in FIG. 5C), which screen the ferroelectric polarization, the trapped charges at the FE-DE interface form a dipole with the same polarity as the ferroelectric polarization, thereby augmenting the MW.

While trapped charges are typically associated with retention degradation due to their detrapping over time, FIG. 4D shows the example FEFET having the engineered FE stack (Band-engineered FEFET) demonstrates robust retention at both room temperature and 50° C. FIG. 4D is a graph showing the threshold voltage (Vt) retention at room temperature (RT) and 50° C. for the example FEFET having an engineered ferroelectric gate stack (Band-engineered FEFET). In FIG. 4D, the triangle data characters are data for room temperature and the square data characters are data for 50° C.]

FIG. 5A is a diagram illustrating a pulse scheme for disturb characterization of FEFETs according to experimental examples. FIG. 5B is a diagram illustrating characterization of FEFET threshold voltages according to experimental examples. FIG. 5C is a schematic of a gate stack and band diagram for explaining electron injection from the channel side when the positive pass voltage is applied to the gate electrode of a FEFET having an engineering ferroelectric gate stack (Band-engineered FEFET).

Disturb characterization on the Standard FEFET and the Band-engineered FEFET examples were done at three voltage conditions: Vpass=V_{T}, V_{T}+1V and V_{T}+2V, with 50 μs pulses using the pulse scheme depicted in FIG. 5A. The Disturb pulses in FIG. 5A correspond to the three voltage conditions for Vpass in the disturb characterization. The evolution of V_{T} with disturb pulses at different disturb voltages is presented in FIGS. 5B and 5C for the Standard FEFET and Band-engineered FEFET examples. FIGS. 5B and 5C show that ΔV_{T} in the PGM state of the Band-engineered FEFET is similar to that in the Standard FEFET. However, relative to the memory window MW, pass disturb in the PGM state of the band-engineered FEFET (31% @Vpass=V_{T}+2 V) is 2.5 times lower than that in the standard FEFET (71% @Vpass=V_{T}+2 V).

In the PGM state, ferroelectric polarization points towards the channel. As such, no polarization switching is expected during disturb pulses in the PGM state, as the field during these pulses aligns with the ferroelectric polarization. The observed positive shift in the threshold voltage during disturb cycling in the PGM state is similar to the positive bias temperature instability (PBTI) where it is attributed to electron trapping in the gate stack due to positive voltage pulses. The possibility of electron injection from the channel side is further reinforced by the electric field across the gate stack under a positive pass voltage pulse, which points toward the channel, as shown in the band diagram in FIG. 5C.

### Disturb Mitigation Scheme

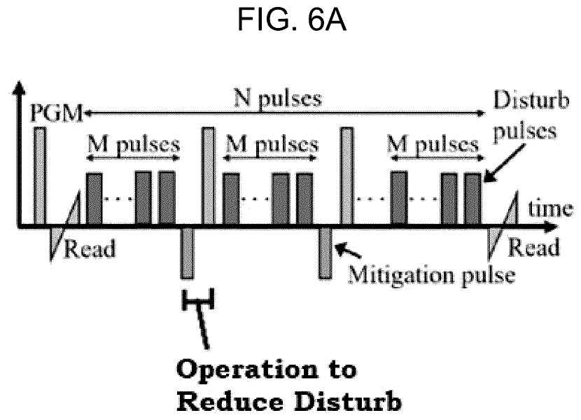

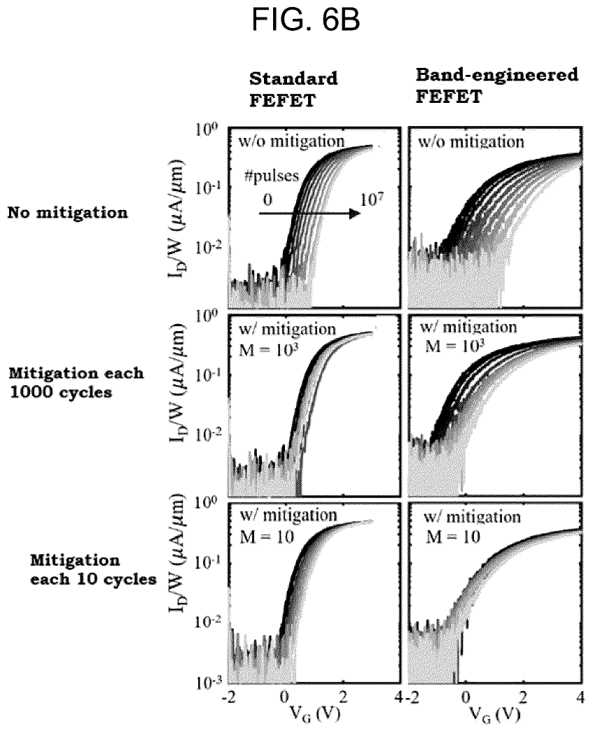

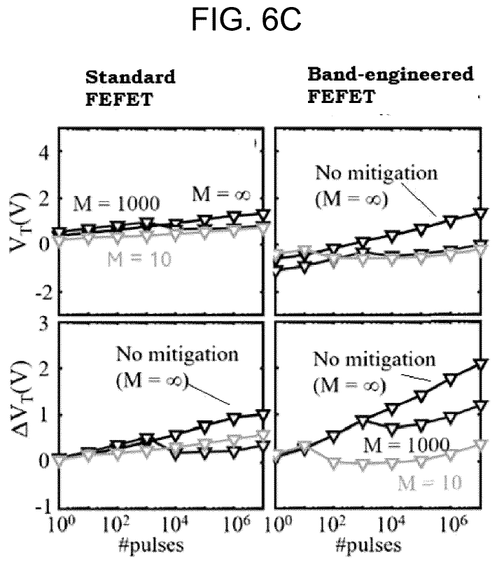

Based on this hypothesis, the inventors applied periodic refresh pulses of negative voltage at different pulse intervals (M) to detrap the trapped electrons in FEFETs according to experimental examples. Following each negative refresh pulse, a positive PGM pulse was applied to restore the state of the FEFET cell. The refresh scheme is depicted in FIG. 6A.

FIG. 6A is a diagram illustrating a disturb mitigation pulse scheme including an operation to reduce disturb according to an example embodiment. In FIG. 6A, the negative refresh pulse is labeled as a Mitigation pulse. The disturb mitigation pulse scheme illustrated in FIG. 6A includes an Operation to Reduce Disturb where the negative Mitigation pulse is followed by the positive PGM pulse.

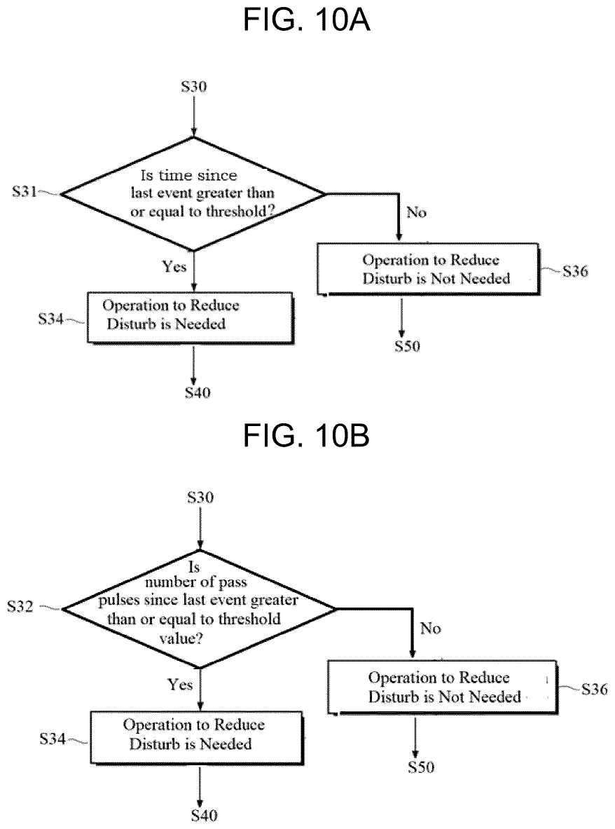

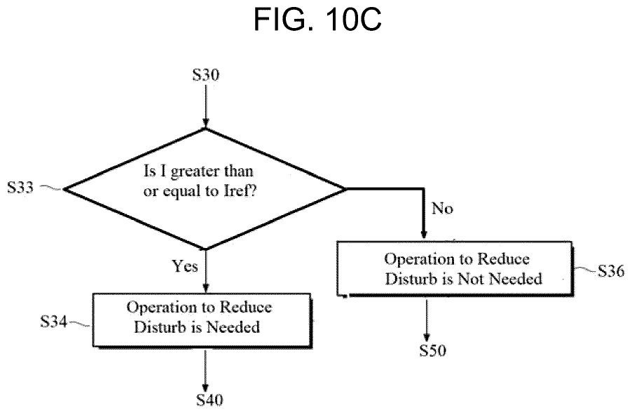

The evolution of the transfer characteristics with refresh pulses applied at different refresh periods, M, is shown in FIGS. 6B and 6C. FIG. 6B includes I_{D}-V_{G} curves for standard and band-engineered FEFETs after different numbers of disturb cycles (@Vt+2 V) with no mitigation and refresh every 1000 and 10 cycles. FIG. 6C illustrates the evolution of threshold voltage (V_{T}) and ΔV_{T} for standard and band-engineered FEFETs in threshold voltage according to experimental examples. For the data shown in FIGS. 6B and 6C, 10 μs refresh pulses of −7 V and −10 V were used for the standard and band-engineered FEFETs, respectively. V_{T} and ΔV_{T} as a function of the #pulses are shown in FIG. 6C. The top two graphs in FIG. 6B show the I_{D}-V_{G} curves for standard and band-engineered FEFETs when no mitigation is performed after the number of disturb pulses M is increased. The middle two graphs in FIG. 6B show the I_{D}-V_{G} curves for standard and band-engineered FEFETs when mitigation was performed after every 1000 cycles of disturb pulses (M=103). The low two graphs in FIG. 6B show the I_{D}-V_{G} curves for standard and band-engineered FEFETs when mitigation was performed after every 10 cycles of disturb pulses (M=10). In FIG. 6B, the left side of I_{D}-V_{G} curves is for the Standard FeFET and the right side of I_{D}-V_{G} curves is for the Band-engineered FeFET.

Referring to FIGS. 6B and 6C, it was clearly observed that frequent “refreshing” can reduce the pass disturb significantly in both the standard and band-engineered FEFETs. With a proper choice of M, the relative pass disturb (ΔV_{T}/MW) after 10⁷ disturb pulses was reduced from ˜28% in the unmitigated case (M=∞) down to ˜4% (M=10) in the band-engineered FEFET.

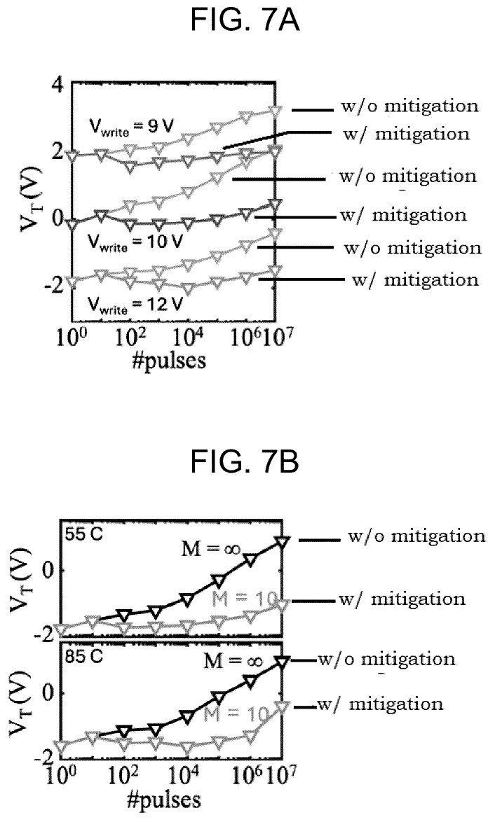

Additionally, the effectiveness of the mitigation scheme across different program states and at different temperatures is also demonstrated in FIGS. 7A and 7B. FIGS. 7A and 7B are graphs illustrating the efficacy of a disturb mitigation scheme (M=10) with disturb cycling (@V_{T}+2V) on band-engineered FEFETs according to experimental examples for: (a) different states of without mitigation (w/o mitigation) and with mitigation (w/ mitigation), as shown in FIG. 7A, and (b) different temperatures are demonstrated in FIG. 7B.

The efficacy of the periodic refresh pulse scheme in reducing the disturb effect further bolsters the hypothesis that pass disturb in the PGM state originates from charge trapping rather than undesired polarization switching. In other words, the positive V_{T} shift during disturb pulses is caused by electron trapping in the gate stack akin to PBTI and can be removed or detrapped by the negative refresh pulses.

In summary, a comparative analysis of disturb effects in standard and band-engineered FEFETs was performed. The inventors observed that although inserting a dielectric layer triples the memory window, the PGM state exhibits similar disturb characteristics in both configurations. To maintain the disturb characteristics within manageable limits, a disturb mitigation scheme based on periodic refresh pulses was proposed. By reducing pass disturb from approximately 28% to around 4% of the MW, the mitigation scheme also supports the hypothesis that electron trapping is the primary cause for disturbance in the PGM state.

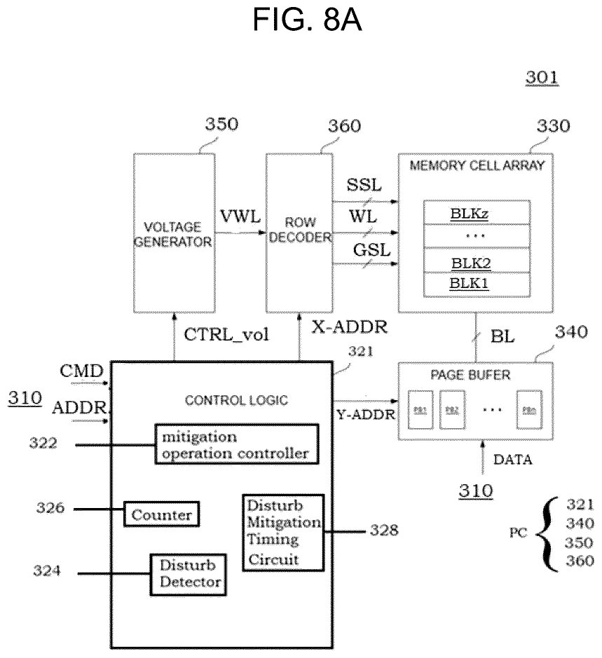

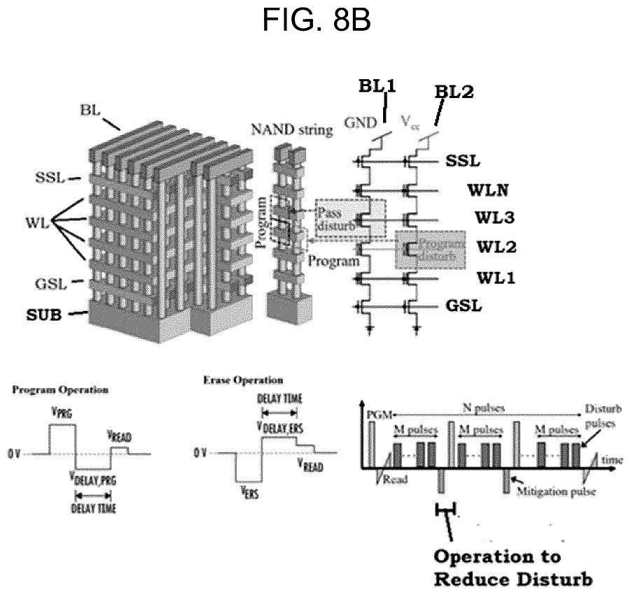

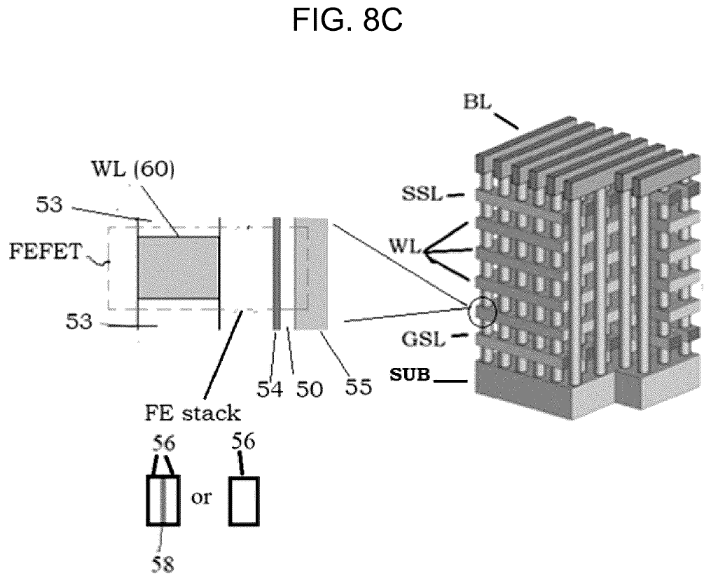

FIG. 8A is a block diagram of a memory device according to an example embodiment. FIG. 8B is an example diagram for a portion of a memory block in the memory cell array in the memory device of FIG. 8A. FIG. 8C is a diagram illustrating an enlarged view of a FEFET in the portion of the memory block in FIG. 8B.

Referring to FIGS. 8A and 8B, the memory device 301 in FIG. 8A may be substantially the same as the memory device 300 in FIG. 3A, except the control logic 321 in the memory device 301 may be different than the control logic 320 in the memory device 300.

The control logic 321 may be configured to perform an operation to reduce disturb on one or more ferroelectric field effect transistors (FEFETs) in the memory cell array 330. The operation to reduce disturb in the FEFET may include applying a mitigation pulse to a gate electrode of a FEFET using a word line connected to the gate electrode of the FEFET and then applying a program pulse to the gate electrode of the FEFET using the word line. One of the bit lines BL may be connected to a drain region of a semiconductor layer in FEFET. The control logic 321 may be configured to perform the disturb mitigation scheme described in FIG. 6A on one or more FEFETs in the memory cell array 330. The disturb mitigation scheme may include cycles of an operation to reduce disturb. In the operation to reduce disturb, the applying the positive PGM pulse may be performed immediately after the applying the mitigation pulse without a delay time in between.

In some embodiments, the control logic 321 may include a mitigation operation controller 322 and at least one of a disturb detector 324, a counter 326, or a disturb mitigation timing circuit 328 for performing the operation to reduce disturb and/or disturb mitigation scheme according to example embodiments. The control logic 321, page buffer 340, voltage generator 350, and row decoder 360 may be included in processing circuitry PC.

Referring to FIG. 8C, a FEFET in the portion of the memory block example shown in FIG. 8B may include the same structure as the FEFET 200b described in FIG. 2B. In FIG. 8C, a portion of a word line WL may define the conductor layer 60 of the FEFET and may define the gate electrode of the FEFET. The FEFET in FIG. 8C may include a portion of a FE stack and a portion of interfacial layer 54 between the conductor layer 60 and a portion of the semiconductor layer 50. The conductor layer 60, FE stack, interfacial layer 54, semiconductor layer 50, and insulating filler 55 may be directly connected to each other. The FE stack in FIG. 8C may include a single ferroelectric layer 56 or the FE stack may include a band-engineered FE stack having a tunnel dielectric layer 58 directly between a pair of ferroelectric layers 56.

The FEFET in FIG. 8C may correspond to a memory cell in the memory cell array 330 of the memory device 301 in FIG. 8A. FIG. 8C shows how each word line WL may be alternately stacked in a vertical direction with insulating layers 53. Like the word lines WL in FIGS. 8B and 8C, the insulating layers 53 may surround the FE stack, interfacial layer 54, semiconductor layer 50, and insulating filler 55 of the NAND strings. Although not shown in FIG. 8C, the insulating filler 55 optionally may be omitted, in which case the semiconductor layer 50 may fill an area occupied by the insulating filler 55.

Although the FIGS. 8B and 8C are example structures for a portion of a memory block in the memory cell array in the memory device of FIG. 8A and an enlarged view of a FEFET in FIG. 8B, example embodiments are not limited thereto. The memory blocks BLK1 to BLKz in the memory cell array 330 of FIG. 8A alternatively may have planar structures like the FEFET 200a described in FIG. 2A.

A threshold voltage of a ferroelectric transistor (FEFET) may change from a first level to a second level that is higher than the first level after a plurality of pass pulses are applied to the ferroelectric transistor following a program operation on the ferroelectric transistor. For example, the curves in FIG. 6C show an increase in ΔV_{T} from 10⁰ pulses to 107 pulses when no mitigation is applied to the Standard FEFET and Band-Engineered FEFET.

According to example embodiments, by performing the operation to reduce disturb on a FEFET and/or by performing the disturb mitigation scheme in FIG. 6A of the present application that includes the operation to reduce disturb, the control logic 321 may restore the threshold voltage of a FEFET from a second level (e.g., see e.g., a drifted threshold voltage V_{T} in FIG. 6C as the #pulses increases for the M=∞ curve) to a first level (See e.g., V_{T} in the M=10 and M=1000 curves for the Band-engineered FEFET in FIG. 6C). Additionally, the control logic 321 may be configured to restore one or more threshold voltages of one or more of a plurality of ferroelectric transistors in one or more of the plurality of NAND strings in the memory cell array 330 of the memory device 301 from one or more drifted threshold voltages to one or more desired threshold voltages, respectively, by performing the operation to reduce disturb on the one or more of the plurality of ferroelectric transistors in the one or more of the plurality of NAND strings.

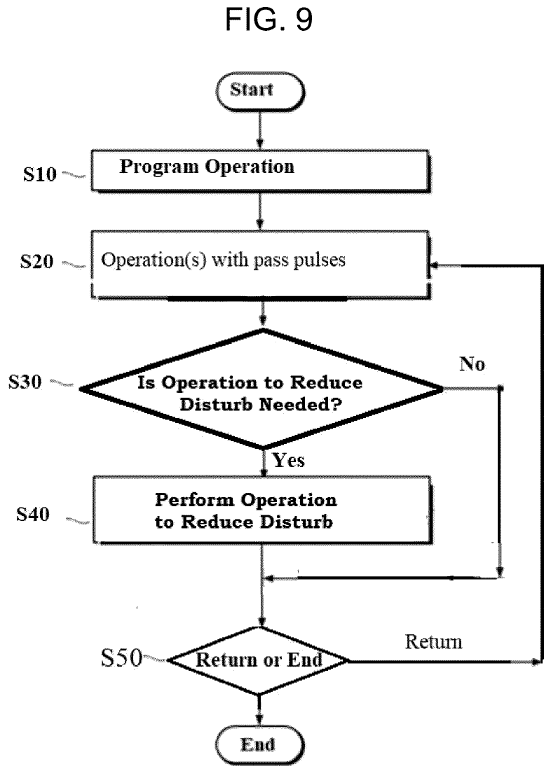

FIG. 9 is a flow chart for a method of operating a memory device according to an example embodiment. The FEFET described in connection with FIG. 9 may have the structure of the FEFET in FIG. 8C, FEFET 200a in FIG. 2A, or FEFET 200b in FIG. 2B. Accordingly, structural details thereof are not repeated with the discussion of FIGS. 9, 10A, 10B, and 10C.

Referring to FIGS. 6A, 8A, 8B and 9, in operation S10, the control logic 321 of the memory device 301 may perform a program operation.

The program operation may be performed on a ferroelectric transistor (FEFET) of the memory device 301 to set a threshold voltage of the FEFET. Details of the program operation are shown in FIG. 8B so a description of the program operation is not repeated.

In operation S20, the control logic 321 may perform one or more operations that include applying one or more pass pulses to the FEFET. For example, during read and write operations, the control logic 321 may apply a pass voltage greater than the threshold voltage V_{T} of the erase (ERS) state to turn on unaddressed cells (or unselected FEFETs) in the bit line BL. Thus, control logic 321 may apply pass pulses to the FEFET when the FEFET is one of the unaddressed cells in read and write operations.

In operation S30, the control logic 321 may determine whether an operation to reduce disturb is needed. If the control logic 321 determines the operation to reduce disturb is needed, then the control logic 321 may perform the operation S40 to reduce disturb in the FEFET and then proceed to operation S50.

In operation S40, the operation to reduce disturb may include applying a mitigation pulse to the gate electrode of the FEFET using a word line and then applying a program pulse to the gate electrode of the FEFET using the word line. As shown in FIGS. 6A and 8B, the mitigation pulse may be negative and a polarity of the mitigation pulse may be opposite a polarity of the program pulse PGM. The program pulse may be positive relative to a source region of the semiconductor layer 50 in the FEFET. A level of the program pulse PGM may correspond to a level of a write voltage sufficient to program a desired program state in the FEFET. A level of the mitigation pulse may be sufficient to detrap electrons in the ferroelectric transistor (FEFET). In the operation to reduce disturb S40, the applying the program pulse to the gate electrode of the FEFET performed immediately after the applying the mitigation pulse to the gate electrode of the FEFET without a delay time in between.

In operation S50, the control logic 321 determines whether to return to operation S20 or end the method in FIG. 9. For example, after the mitigation pulse and program pulse are applied to the FEFET in the operation to reduce disturb (see FIG. 6A), the control logic 321 may return to operation S20 and perform operation(s) that include applying pass pulses to the FEFET. Returning to operation S20 may be analogous to performing another cycle of M pulses in FIG. 6A. Alternatively, in operation S50, the control logic 321 may end the method in FIG. 9 to perform a different operation on FEFET such as an operation where a pass pulse is not applied to the FEFET.

When, in operation S50, the control logic 321 returns to operation S20 and repeats cycles of operation S20, S30 (yes), S40, and S50 (Return), the control logic 321 may periodically repeat the operation to reduce disturb S40 in the FEFET a plurality of times after the performing the program operation S10 is performed a single time. The control logic 321 may periodically repeat the operation to reduce disturb S40 according to time intervals (see S31 in FIG. 10A), detecting whether the number of pass pulses since a last event is greater than or equal to a threshold value (see S32 in FIG. 10B), and/or detecting whether a current I of the FEFET is greater than or equal to a reference current Iref (see S33 in FIG. 10C).

In operation S30, when the control logic 321 determines the operation to reduce disturb is not needed, the control logic 321 may proceed from operation S30 to operation S50 without performing operation S40 in between.

Examples for the control logic 321 performing operation S30 are described in connection with FIGS. 10A, 10B, and 10C. Additionally, although not illustrated, the control logic 321 also may determine the operation to reduce disturb is needed or not needed in operation S30 based on a command received from an external host.

FIG. 10A is a flowchart for describing an operation for detecting whether an operation to reduce disturb is needed according to an example embodiment. FIG. 10B is a flowchart for describing an operation for detecting whether an operation to reduce disturb is needed according to an example embodiment. FIG. 10C is a flowchart for describing an operation for detecting whether an operation to reduce disturb is needed according to an example embodiment.

Referring to FIGS. 8A, 9, and 10A, in operation S31, the control logic 321 may check whether an elapsed time since a last event is greater than or equal to a threshold value, where the last event may be selected among a most-recent operation among the program operation S10 on the FEFET or a previous operation to reduce to disturb S40 on the FEFET. The threshold value in operation S31 may be a time limit for the time interval between consecutive cycles of the operation to reduce disturb operation in S40. The threshold value for the time limit in operation S31 may be set based on a time limit for a desired level of disturb mitigation and may be based on characterization of the memory device 301.

If, in operation S31, the elapsed time since the last event is greater than or equal to the threshold value, then the control logic 321 may proceed to operation S34 and determine the operation to reduce disturb is needed. After operation S34, the control logic 321 may proceed to operation S40 in FIG. 9 and perform the operation to reduce disturb on the FEFET.

If, in operation S31, the elapsed time since the last event is not greater than or equal to the threshold value, then the control logic 321 may proceed to operation S36 and determine the operation to reduce disturb is not needed. After operation S36, the control logic 321 may proceed to operation S50 in FIG. 9.

In some embodiments, in operation S31, the disturb mitigation timing circuit 328 may provide a different command or signal to the mitigation operation controller 322 based on whether the time interval since the last event (e.g., most recent operation among program operation S10 or a previous operation to reduce disturb in S40 of FIG. 9) is greater than or equal to the threshold value. In response to receiving the command or signal from the disturb mitigation timing circuit 328, the mitigation operation controller 322 may determine for the control logic 321 whether the control logic 321 proceeds to operation S34 or operation S36 in FIG. 10A. For example, in operation S31, the disturb mitigation timing circuit 328 may signal or command the mitigation operation controller 322 to make control logic 321 proceed to operation S34 if the time since the last event is greater than or equal to the threshold value; conversely, the disturb mitigation timing circuit 328 may signal or command the mitigation operation controller 322 to make control logic 321 to proceed to operation S36 if the time since the last event is not greater than or equal to the threshold value. Through the disturb mitigation timing circuit 328, the control logic 321 may control a time interval between repeated cycles of the operation to reduce disturb in S40.

Referring to FIGS. 8A, 9, and 10B, in operation S32, the control logic 321 may check whether the number of pass pulses applied to the FEFET since a last event is greater than or equal to a threshold value, where the last event may be selected among a most-recent operation among the program operation S10 on the FEFET or a previous operation to reduce to disturb S40 on the FEFET. The threshold value in operation S32 may be a limit for the number of pass pulses applied to the FEFET between consecutive cycles of the operation to reduce disturb operation in S40. The threshold value for the number of pass pulses in operation S32 may be set based on a level needed for a desired level of disturb mitigation and may be based on characterization of the memory device 301.

If, in operation S32, the number of pass pulses since the last event is greater than or equal to the threshold value, then the control logic 321 may proceed to operation S34 and determine the operation to reduce disturb is needed. After operation S34, the control logic 321 may proceed to operation S40 in FIG. 9 and perform the operation to reduce disturb on the FEFET.

If, in operation S32, the number of pass pulses since the last event is not greater than or equal to the threshold value, then the control logic 321 may proceed to operation S36 and determine the operation to reduce disturb is not needed. After operation S36, the control logic 321 may proceed to operation S50 in FIG. 9.

In some embodiments, in operation S32, the counter 326 (e.g., counter circuit) may provide a different command or signal to the mitigation operation controller 322 based on whether the number of pass pulses since the last event (e.g., most recent operation among program operation S10 or a previous operation to reduce disturb in S40 of FIG. 9) is greater than or equal to the threshold value for operation S32. In response to receiving the command or signal from the counter 326, the mitigation operation controller 322 may determine for the control logic 321 whether the control logic 321 proceeds to operation S34 or operation S36 in FIG. 10B. For example, in operation S32, the counter 326 may signal or command the mitigation operation controller 322 to make control logic 321 proceed to operation S34 if the number of pass pulses since the last event is greater than or equal to the threshold value; conversely, the counter 326 may signal or command the mitigation operation controller 322 to make control logic 321 proceed to operation S36 if the number of pass pulses since the last event is not greater than or equal to the threshold value. In some embodiments, the counter 326 may be a counter circuit in a peripheral area of the memory device 301. Accordingly, the control logic 321 may be configured to perform the operation to reduce disturb S40 in the FEFET in response to the control logic 321 detecting the number of pass pulses applied to the ferroelectric transistor is greater than or equal to a threshold level.

Referring to FIGS. 8A, 9, and 10C, in operation S32, the control logic 321 may detect whether a current I of the FEFET is greater than or equal to a reference current Iref. The reference current Iref in operation S32 may be a control limit for the current I of the FEFET corresponding to a desired state or V_{T} of the FEFET, but is not limited thereto. The control logic 321 may detect the current I of the FEFET by performing a read operation on the FEFET.

If, in operation S33, the current I of the FEFET is greater than or equal to the reference current Iref, then the control logic 321 may proceed to operation S34 and determine the operation to reduce disturb is needed. After operation S34, the control logic 321 may proceed to operation S40 in FIG. 9 and perform the operation to reduce disturb on the FEFET.

If, in operation S33, the current I of the FEFET is not greater than or equal to the reference current Iref, then the control logic 321 may proceed to operation S36 and determine the operation to reduce disturb is not needed. After operation S36, the control logic 321 may proceed to operation S50 in FIG. 9.

In some embodiments, in operation S33, the disturb detector 324 (e.g., logic circuit) may provide a different command or signal to the mitigation operation controller 322 based on whether the current I of the FEFET is greater than or equal to the reference current Iref. In response to receiving the command or signal from the disturb detector 324, the mitigation operation controller 322 may determine for the control logic 321 whether the control logic 321 proceeds to operation S34 or operation S36 in FIG. 10C. For example, in operation S33, the disturb detector 324 may signal or command the control logic 321 to proceed to operation S34 if the current I is greater than or equal to the reference current Iref; conversely, the disturb detector 324 may signal or command the control logic 321 to proceed to operation S36 if the current I is not greater than or equal to the reference current Iref. Accordingly, the control logic 321 may be configured to perform the operation to reduce disturb S40 in the FEFET in response to the control logic reading a current of the FEFET and detecting whether the current I of the ferroelectric transistor is greater than or equal to a reference current Iref.

Referring to FIGS. 8A to 8C, each block BLK in the memory cell array 330 may include a plurality of NAND strings on a surface of the substrate SUB. The plurality of NAND strings each may include a plurality of ferroelectric transistors connected in series between a first select transistor and a second select transistor. The first select transistor may correspond to the transistor connected to the string selection line SSL in FIG. 8B and the second selected transistor may correspond to the transistor connected to the ground selection line in FIG. 8B. The control logic 321 may be connected to the NAND strings of the memory cell array 330 through word lines WL and bit lines BL. The NAND strings each may extend in a direction perpendicular to a surface of the substrate SUB.

The control logic 321 may reduce disturb in the memory cell array 330 by performing the disturb mitigation scheme in FIG. 6A on the plurality of NAND strings in the memory cell array 330 and/or by performing the method in connection with FIGS. 9, 10A, 10B, and/or 10C on the plurality of NAND strings in the memory cell array 330. In each corresponding ferroelectric transistor among the plurality of ferroelectric transistors in a corresponding NAND string among the plurality of NAND strings, the disturb mitigation scheme may include periodically performing an operation to reduce disturb on the corresponding ferroelectric transistor. The operation to reduce disturb on the corresponding ferroelectric transistor may be periodically performed in response to the control logic detecting the operation to reduce disturb is needed (see S30 in FIG. 9 and FIGS. 10A to 10C) for the corresponding ferroelectric transistor. As shown in FIGS. 6A and 8B, the operation to reduce disturb may include applying a mitigation pulse to a gate electrode of the corresponding ferroelectric transistor followed by a program pulse to the gate electrode of the corresponding ferroelectric transistor. The control logic may apply the mitigation pulse and the program pulse to the corresponding ferroelectric transistor using a corresponding word line among the plurality of word lines WL and a corresponding bit line among the plurality of bit lines BL. The corresponding word line may be connected to the corresponding ferroelectric transistor. The corresponding bit line may be connected to the corresponding NAND string. A polarity of the mitigation pulse may be opposite a polarity of the program pulse. A level of the mitigation pulse may be sufficient to detrap electrons in the corresponding ferroelectric transistor. A level of the program pulse may correspond to a level of a write voltage sufficient to program a desired program state in the corresponding ferroelectric transistor.

In the operation to reduce disturb, operation S40 in FIG. 9, the program pulse may be applied to the gate electrode of the corresponding ferroelectric transistor immediately after the mitigation pulse is applied to the gate electrode of the corresponding ferroelectric transistor without a delay time in between. As shown in FIG. 8C, the word line WL may be connected to a conductor layer 60 of the corresponding FEFET.

Referring to FIGS. 8A to 8C, in the memory cell array 330, the plurality of NAND strings each may include a semiconductor layer 50 extending in a direction perpendicular to a surface of the substrate SUB, an interfacial layer 54 surrounding the semiconductor layer 50 and containing an oxide of a material of the semiconductor layer 50, a ferroelectric FE stack surrounding the interfacial layer 54, and a plurality of gate electrodes surrounding the ferroelectric FE stack and spaced apart from each other on the ferroelectric FE stack in a direction perpendicular to the surface of the substrate SUB.

As shown in FIG. 8C, the gate electrodes may correspond to a portion of one of the word lines WL, which may define the conductor layer 60. The ferroelectric FE stack may include one ferroelectric layer 56 or the ferroelectric FE stack may include a plurality of ferroelectric layers 56 extending in the direction perpendicular to the surface of the substrate SUB and separated from each other by a tunnel dielectric layer 54.

In the plurality of NAND strings, the plurality of gate electrodes (e.g., portions of word lines WL) may be alternately stacked with insulating layers 53 in the direction perpendicular to the surface of the substrate SUB. The plurality of insulating layers 53 surround the FE stack. When the FE stack includes a plurality of ferroelectric layers 56 separated by the tunnel dielectric layer 58, the plurality of ferroelectric layers 56 may extend the direction perpendicular to the surface of the substrate SUB and may be separated from each other by the tunnel dielectric layer 54, the interfacial layer 54 may directly contact the semiconductor layer 50, and the gate electrode (e.g., portions of word line WL) may directly contact an outer ferroelectric layer 56 among ferroelectric layers in the FE stack.

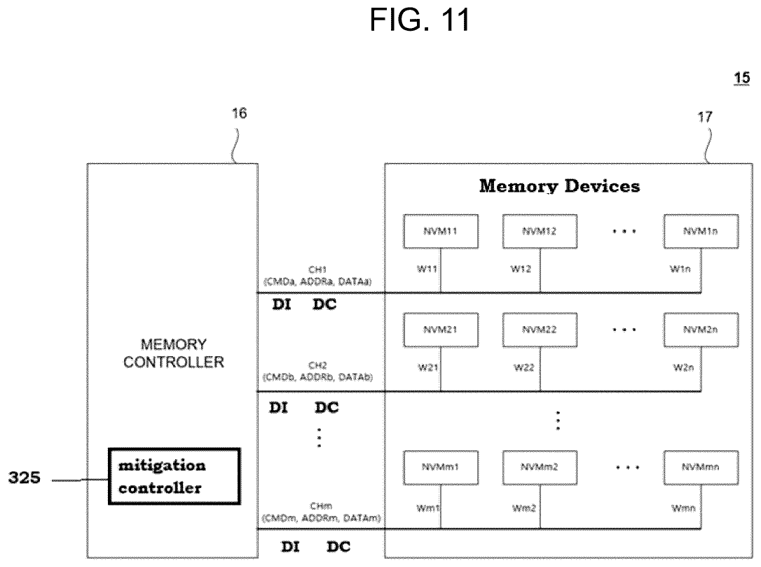

FIG. 11 is a block diagram of a memory system 15 according to an example embodiment.

Referring to FIG. 11, the memory system 15 may include memory devices 17 and a memory controller 16. The memory system 15 may support a plurality of channels CH1 to CHm, and the memory devices 17 may be connected to the memory controller 16 through the plurality of channels CH1 to CHm. For example, the memory system 15 may be implemented as a storage device, such as an SSD.

The memory devices 17 may include a plurality of NVM devices NVM11 to NVMmn. Each of the NVM devices NVM11 to NVMmn may be connected to one of the plurality of channels CH1 to CHm through a way corresponding thereto. For instance, the NVM devices NVM11 to NVMIn may be connected to a first channel CH1 through ways W11 to Win, and the NVM devices NVM21 to NVM2n may be connected to a second channel CH2 through ways W21 to W2n. In an example embodiment, each of the NVM devices NVM11 to NVMmn may be implemented as an arbitrary memory unit that may operate according to an individual command from the memory controller 16. For example, each of the NVM devices NVM11 to NVMmn may be implemented as a chip or a die including the memory device 301 according to example embodiments in FIGS. 8A to 8C, but example embodiments are not limited thereto.

The memory controller 16 may transmit and receive signals to and from the memory devices 17 through the plurality of channels CH1 to CHm. For example, the memory controller 16 may transmit commands CMDa to CMDm, addresses ADDRa to ADDRm, and data DATAa to DATAm to the memory devices 17 through the channels CH1 to CHm or receive the data DATAa to DATAm from the memory devices 17.

The memory controller 16 may select one of the NVM devices NVM11 to NVMmn, which is connected to each of the channels CH1 to CHm, by using a corresponding one of the channels CH1 to CHm, and transmit and receive signals to and from the selected NVM device. For example, the memory controller 16 may select the NVM device NVM11 from the NVM devices NVM11 to NVMIn connected to the first channel CH1. The memory controller 16 may transmit the command CMDa, the address ADDRa, and the data DATAa to the selected NVM device NVM11 through the first channel CH1 or receive the data DATAa from the selected NVM device NVM11.

The memory controller 16 may transmit and receive signals to and from the memory devices 17 in parallel through different channels. For example, the memory controller 16 may transmit a command CMDb to the memory devices 17 through the second channel CH2 while transmitting a command CMDa to the memory devices 17 through the first channel CH1. For example, the memory controller 16 may receive data DATAb from the memory devices 17 through the second channel CH2 while receiving data DATAa from the memory devices 17 through the first channel CH1.

The memory controller 16 may control all operations of the memory devices 17. The memory controller 16 may transmit a signal to the channels CH1 to CHm and control each of the NVM devices NVM11 to NVMmn connected to the channels CH1 to CHm. For instance, the memory controller 16 may transmit the command CMDa and the address ADDRa to the first channel CH1 and control one selected from the NVM devices NVM11 to NVMIn.

Each of the NVM devices NVM11 to NVMmn may operate via the control of the memory controller 16. For example, the NVM device NVM11 may program the data DATAa based on the command CMDa, the address ADDRa, and the data DATAa provided to the first channel CH1. For example, the NVM device NVM21 may read the data DATAb based on the command CMDb and the address ADDb provided to the second channel CH2 and transmit the read data DATAb to the memory controller 16.

Although FIG. 11 illustrates an example in which the memory devices 17 communicates with the memory controller 16 through m channels and includes n NVM devices corresponding to each of the channels, the number of channels and the number of NVM devices connected to one channel may be variously changed.

The memory controller 16 may include a mitigation controller 325 for controlling a disturb mitigation scheme on any one of the NVM devices NVM11 to NVMmn. For example, the memory controller 16 may receive disturb information DI from the nonvolatile memory devices NVM devices NVM11 to NVMmn through the channels CH1 to CHm, the mitigation controller 325 may process the disturb information DI, and the memory controller 16 may issue disturb commands DC to the nonvolatile memory devices NVM devices NVM11 to NVMmn based on a result of the mitigation controller 325 processing the disturb information DI.

For example, referring to FIGS. 8A, 9, 10A to 10C, and 11, the disturb information DI may include information from a NVM device (e.g., one of the nonvolatile memory devices NVM devices NVM11 to NVMmn) related to whether the time since the last event is greater than or equal to a threshold value (see FIG. 10A, operation S31), the number of pass pulses since last event is greater than or equal to a threshold value (see FIG. 10B, operation S32), or whether the current I is greater than or equal to Iref. If the time since the last event is greater than or equal to the threshold value for operation S31 in FIG. 10A, the number of pass pulses since the last event is greater than or equal to the threshold value for operation S32 in FIG. 10B, or the current I is greater than or equal to Iref for operation S33 in FIG. 10C, then the mitigation controller 325 may process that disturb information DI and cause the memory controller 16 to generate a disturb command DC that commands the NVM device to perform an operation to reduce disturb.

Conversely, if the time since the last event is not greater than or equal to the threshold value for operation S31 in FIG. 10A, the number of pass pulses since the last event is not greater than or equal to the threshold value for operation S32 in FIG. 10B, or the current I is not greater than or equal to Iref for operation S33 in FIG. 10C, then the mitigation controller 325 may process that disturb information DI and cause the memory controller 16 to generate a disturb command DC that commands the NVM device to no perform an operation to reduce disturb.

According to example embodiments, a memory device and memory system including the same may implement a disturb mitigation scheme to reduce disturb in FEFETs. The disturb mitigation scheme may include a periodic operation to reduce disturb on the FEFETs. The memory device and memory system including the same may implement the periodic operation to reduce disturb in response to detecting the operation to reduce disturb is needed. Accordingly, reliability of the memory device and memory system may be improved by reducing disturb in the FEFETs.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the example embodiments have been illustrated and described above, it will be configured as apparent to those skilled in the art that modifications and variations could be made without departing from the scope of the present disclosure as defined by the appended claims.

What is claimed is:

1. A memory device, comprising:
a ferroelectric transistor including a semiconductor layer, a gate electrode on the semiconductor layer, an interfacial layer between the gate electrode and the semiconductor layer, and a ferroelectric layer between the interfacial layer and the gate electrode;
a word line connected to the gate electrode;
a bit line connected a drain region of the semiconductor layer
processing circuitry connected to the ferroelectric transistor through the word line and the bit line, wherein
the processing circuitry is configured to perform an operation to reduce disturb in the ferroelectric transistor by applying a mitigation pulse to the gate electrode of the ferroelectric transistor using the word line and then applying a program pulse to the gate electrode of the ferroelectric transistor using the word line,
a polarity of the mitigation pulse is opposite a polarity of the program pulse, and
a level of the program pulse corresponds to a level of a write voltage sufficient to program a desired program state in the ferroelectric transistor.

2. The memory device of claim 1, wherein
the mitigation pulse is negative and a level of the mitigation pulse is sufficient to detrap electrons in the ferroelectric transistor,
the level of the program pulse is positive relative to a source region of the semiconductor layer, and
in the operation to reduce disturb, the applying the program pulse to the gate electrode of the ferroelectric transistor is performed immediately after the applying the mitigation pulse to the gate electrode of the ferroelectric transistor without a delay time in between.

3. The memory device of claim 1, wherein
the ferroelectric layer directly contacts the interfacial layer and the gate electrode directly contacts the ferroelectric layer, and
the ferroelectric layer is one single ferroelectric layer between the interfacial layer and the gate electrode, and
the ferroelectric transistor is a memory cell in a memory cell array of the memory device.

4. The memory device of claim 1, wherein
the ferroelectric layer is a first ferroelectric layer,
the ferroelectric transistor further includes a tunnel dielectric layer on the first ferroelectric layer and a second ferroelectric layer on the tunnel dielectric layer,
the interfacial layer includes an oxide of a material of the semiconductor layer,
the gate electrode is on the second ferroelectric layer, and
the ferroelectric transistor is a memory cell in a memory cell array of the memory device.

5. The memory device of claim 4, wherein
the first ferroelectric layer and the second ferroelectric layer each include hafnium zirconium oxide,
the interfacial layer, the first ferroelectric layer, the tunnel dielectric layer, and the second ferroelectric layer are stacked directly on top of each other between the semiconductor layer and the gate electrode,
the material of the semiconductor layer includes silicon, and
a thickness of a stack including the first ferroelectric layer, the tunnel dielectric layer, and the second ferroelectric layer is less than or equal to 20 nm in a direction from the interfacial layer to the gate electrode.

6. The memory device of claim 4, further comprising:
a substrate, wherein
the semiconductor layer is on a surface of the substrate and extends in a direction perpendicular to the surface of the substrate, and
the interfacial layer, the first ferroelectric layer, the tunnel dielectric layer, the second ferroelectric layer, and the gate electrode sequentially surround the semiconductor layer.

7. The memory device of claim 1, wherein
the processing circuitry is configured to periodically perform the operation to reduce disturb in the ferroelectric transistor a plurality of times after the processing circuitry performs one program operation on the ferroelectric transistor, and
the processing circuitry includes a timing circuit configured to control a time interval between each of the plurality of times the processing circuitry performs the operation to reduce disturb.

8. The memory device of claim 1, wherein
a threshold voltage of the ferroelectric transistor changes from a first level to a second level that is higher than the first level after the processing circuitry applies a plurality of pass pulses to the ferroelectric transistor through the word line following the processing circuitry performing one program operation on the ferroelectric transistor,
a level of the plurality of pass pulses is greater than the threshold voltage of the ferroelectric transistor and less than the level of the program pulse,
the plurality of pass pulses are a same polarity as the program pulse, and
the processing circuitry is configured to restore the threshold voltage of the ferroelectric transistor from the second level to the first level by performing the operation to reduce disturb.

9. The memory device of claim 1, wherein
the processing circuitry is configured to perform the operation to reduce disturb in the ferroelectric transistor in response to the processing circuitry reading a current of the ferroelectric transistor and detecting whether the current of the ferroelectric transistor is greater than or equal to a reference current.

10. The memory device of claim 1, wherein
the processing circuitry includes a counter circuit configured to count a number of pass pulses applied to the ferroelectric transistor after an event,
the event is a most recent operation among a program operation on the ferroelectric transistor or a last time the operation to reduce disturb was performed on the ferroelectric transistor, and
the processing circuitry is configured to perform the operation to reduce disturb in the ferroelectric transistor in response to the processing circuitry detecting the number of pass pulses applied to the ferroelectric transistor after the event is greater than or equal to a threshold level.

11. A memory device, comprising:
a substrate;
a memory cell array including a plurality of NAND strings on the substrate,
the plurality of NAND strings each including a plurality of ferroelectric transistors connected in series between a first select transistor and a second select transistor; and
processing circuitry connected to the plurality of NAND strings of the memory cell array through a plurality of word lines and a plurality of bit lines, wherein
the processing circuitry is configured to reduce disturb in the memory cell array by performing an operation to reduce disturb,
in each corresponding ferroelectric transistor among the plurality of ferroelectric transistors in a corresponding NAND string among the plurality of NAND strings, the operation to reduce disturb includes applying a mitigation pulse to a gate electrode of the corresponding ferroelectric transistor followed by a program pulse to the gate electrode of the corresponding ferroelectric transistor,
the processing circuitry applies the mitigation pulse and the program pulse to the corresponding ferroelectric transistor using a corresponding word line among the plurality of word lines and a corresponding bit line among the plurality of bit lines,
the corresponding word line is connected to the corresponding ferroelectric transistor,
the corresponding bit line is connected to the corresponding NAND string,
a polarity of the mitigation pulse is opposite a polarity of the program pulse,
a level of the mitigation pulse is sufficient to detrap electrons in the corresponding ferroelectric transistor, and
a level of the program pulse corresponds to a level of a write voltage sufficient to program a desired program state in the corresponding ferroelectric transistor.

12. The memory device of claim 11, wherein
in the operation to reduce disturb, the program pulse is applied to the gate electrode of the corresponding ferroelectric transistor immediately after the mitigation pulse is applied to the gate electrode of the corresponding ferroelectric transistor without a delay time in between.

13. The memory device of claim 11, wherein
in the memory cell array, the plurality of NAND strings include a first NAND string and a second NAND string extending in a direction perpendicular to an upper surface of the substrate,
the plurality of word lines include 1 to N word lines at different levels over the upper surface of the substrate,
N is an integer corresponding to a number of the plurality of ferroelectric transistors in the first NAND string and the second NAND string, respectively,
each of the 1 to N word lines is connected to one of the plurality of ferroelectric transistors in the first NAND string and one of the plurality of ferroelectric transistors in the second NAND string at a same level,
the plurality of bit lines include a first bit line electrically connected to a first end of the first NAND string and a second bit line electrically connected to a first end of the second NAND string,
the first bit line is not electrically connected to the second NAND string and the second bit line is not electrically connected to the first NAND string,
the processing circuitry is connected to the first select transistor of the first NAND string and the first select transistor of the second NAND string through a first select line, and
the processing circuitry is connected to the second select transistor of the first NAND string and the second select transistor of the second NAND string through a second select line.

14. The memory device of claim 11, wherein
in the memory cell array, the plurality of NAND strings each include a semiconductor layer extending in a direction perpendicular to a surface of the substrate, an interfacial layer surrounding the semiconductor layer and containing an oxide of a material of the semiconductor layer, a ferroelectric (FE) stack surrounding the interfacial layer, and a plurality of gate electrodes surrounding the FE stack and spaced apart from each other on the FE stack in a direction perpendicular to the surface of the substrate, and
the FE stack includes one ferroelectric layer, or
the FE stack includes a plurality of ferroelectric layers extending in the direction perpendicular to the surface of the substrate and separated from each other by a tunnel dielectric layer.

15. The memory device of claim 14, wherein
in the plurality of NAND strings, the plurality of gate electrodes are alternately stacked with a plurality of insulating layers in the direction perpendicular to the surface of the substrate,
the plurality of insulating layers surround the FE stack,
the FE stack includes the plurality of ferroelectric layers extending the direction perpendicular to the surface of the substrate and separated from each other by the tunnel dielectric layer,
the interfacial layer directly contacts the semiconductor layer, and
the gate electrode directly contacts the FE stack.

16. The memory device of claim 11, wherein
the processing circuitry is configured to periodically perform the operation to reduce disturb on one or more of the plurality of ferroelectric transistors in one or more of the plurality of NAND strings after the one or more of the plurality of ferroelectric transistors in the one or more of the plurality of NAND strings are programmed, and
the processing circuitry includes a timing circuit configured to control a time interval between a plurality of times the processing circuitry periodically performs the operation to reduce disturb on the one or more of the plurality of ferroelectric transistors in the one or more of the plurality of NAND strings after the after the one or more of the plurality of ferroelectric transistors in the one or more of the plurality of NAND strings are programmed.

17. The memory device of claim 11, wherein
the processing circuitry is configured to restore one or more threshold voltages of one or more of the plurality of ferroelectric transistors in one or more of the plurality of NAND strings from one or more drifted threshold voltages to one or more desired threshold voltages, respectively, by performing the operation to reduce disturb on the one or more of the plurality of ferroelectric transistors in the one or more of the plurality of NAND strings.
the processing circuitry is configured to restore a threshold voltage of a disturbed ferroelectric transistor among one or more of the plurality of ferroelectric transistors in one or more of the plurality of NAND strings from a drifted threshold voltage to a desired threshold voltage by performing the operation to reduce disturb on the disturbed ferroelectric transistor.

18. The memory device of claim 11, wherein
the processing circuitry includes a counter circuit configured to count a number of pass pulses applied to the corresponding ferroelectric transistor after the processing circuitry performs one program operation on the corresponding ferroelectric transistor or after the processing circuitry performs the operation to reduce disturb on the corresponding ferroelectric transistor, and
the processing circuitry is configured to perform the operation to reduce to disturb on the corresponding ferroelectric transistor in response the processing circuitry detecting the number of pass pulses applied to the corresponding ferroelectric transistor is greater than or equal to a threshold value.

19. The memory device of claim 11, wherein
the processing circuitry is configured to detect a disturbed ferroelectric transistor among the plurality of ferroelectric transistors in the plurality of NAND strings in response to the processing circuitry reading a current of one of the plurality of ferroelectric transistors in one of the plurality of NAND strings and the processing circuitry detecting the current is greater than or equal to a reference current, and
the processing circuitry is configured to perform the operation to reduce disturb on the disturbed ferroelectric transistor in response to the processing circuitry detecting the disturbed ferroelectric transistor.

20. A memory device, comprising:
a substrate;
a memory cell array including a plurality of NAND strings on the substrate,
the plurality of NAND strings each including a plurality of ferroelectric transistors connected in series between a first select transistor and a second select transistor; and
processing circuitry connected to the plurality of NAND strings of the memory cell array through a plurality of word lines and a plurality of bit lines, wherein
the processing circuitry is configured to reduce disturb in the memory cell array by performing a disturb mitigation scheme,
in each corresponding ferroelectric transistor among the plurality of ferroelectric transistors in a corresponding NAND string among the plurality of NAND strings, the disturb mitigation scheme includes periodically performing an operation to reduce disturb on the corresponding ferroelectric transistor,
the operation to reduce disturb includes applying a mitigation pulse to a gate electrode of the corresponding ferroelectric transistor followed by a program pulse to the gate electrode of the corresponding ferroelectric transistor,
the processing circuitry applies the mitigation pulse and the program pulse to the corresponding ferroelectric transistor using a corresponding word line among the plurality of word lines and a corresponding bit line among the plurality of bit lines,
the corresponding word line is connected to the corresponding ferroelectric transistor,
the corresponding bit line is connected to the corresponding NAND string,
a polarity of the mitigation pulse is opposite a polarity of the program pulse,
a level of the mitigation pulse is sufficient to detrap electrons in the corresponding ferroelectric transistor, and
a level of the program pulse corresponds to a level of a write voltage sufficient to program a desired program state in the corresponding ferroelectric transistor.
